(19) United States
(12) Patent Application Publication
(10) Pub. No.: US 2025/0083949 A1
(43) Pub. Date: Mar. 13, 2025

(54) MEMS ELECTRICALLY CONNECTED PRECISION MOTION STAGE WITH POSITION SENSOR

(71) Applicant: MEMS DRIVE (Nanjing) Co., Ltd., Nanjing (CN)

(72) Inventors: Matthew NG, Rosemead, CA (US); Guiqin WANG, Arcadia, CA (US)

(73) Assignee: MEMS DRIVE (Nanjing) Co., Ltd., Nanjing (CN)

(21) Appl. No.: 18/830,569

(22) Filed: Sep. 10, 2024

Related U.S. Application Data
(60) Provisional application No. 63/581,866, filed on Sep. 11, 2023.

(51) Int. Cl. B81B 3/00; H04N 23/68

(52) U.S. Cl. CPC B81B 3/0062; H04N 23/6812; B81B 2201/0292; B81B 2203/0136; B81B 2203/0172; B81B 2203/051; B81B 2203/056; B81B 2207/053

(57) ABSTRACT

An electrically-connected MEMS precision motion stage includes a stationary portion, one or more electrically-conductive MEMS flexure assemblies coupled to the stationary portion, a movable portion coupled to the one or more electrically-conductive MEMS flexure assemblies, one or more motion control assemblies disposed between the stationary portion and the movable portion and configured to control motion of the movable portion, and one or more position sensors disposed adjacent to the one or more motion control assemblies and configured to enable detection of movement of the one or more motion control assemblies, respectively.

### RELATED APPLICATIONS

This application claims the benefit of U.S. Provisional Application No. 63/581,866 filed on Sep. 11, 2023, the contents of which are incorporated herein by reference.

### FIELD OF DISCLOSURE

This disclosure relates to a motion stage in general and, more particularly, to miniaturized MEMS motion stages configured for use within camera packages.

### BACKGROUND

As is known in the art, actuators may be used to convert electronic signals into mechanical motion. In many applications such as e.g., portable devices, imaging-related devices, telecommunications components, and medical instruments, it may be beneficial for miniature actuators to fit within the small size, low power, and cost constraints of these application.

Micro-electrical-mechanical system (MEMS) technology is a technology that, in its most general form, may be defined as miniaturized mechanical and electro-mechanical elements that are made using the techniques of microfabrication. The critical dimensions of MEMS devices may vary from well below one micron to several millimeters. In general, MEMS actuators are more compact than conventional actuators, and they consume less power.

### SUMMARY

The present disclosure provides a MEMS electrically connected precision motion stage with position sensor. The MEMS motion stage incorporates a flexible electrical connection mechanism as well as a motion control mechanism and a position sensing mechanism.

According to one aspect, a micro-electrical-mechanical system (MEMS) motion stage is provided. The MEMS motion stage includes a stationary portion, one or more electrically-conductive MEMS flexure assemblies coupled to the stationary portion, a movable portion coupled to the one or more electrically-conductive MEMS flexure assemblies, one or more motion control assemblies disposed between the stationary portion and the movable portion and configured to control motion of the movable portion, and one or more position sensors disposed adjacent to the one or more motion control assemblies and configured to enable detection of movement of the movable portion in relation to the stationary portion.

In some example embodiments, the one or more electrically-conductive MEMS flexure assemblies each comprise a plurality of electrically-conductive MEMS flexures.

In some example embodiments, the one or more motion control assemblies each comprise a plurality of motion control flexures.

In some example embodiments, the one or more motion control assemblies each include: an X-axis displacement assembly comprising a plurality of X-axis motion control flexures; and a Y-axis displacement assembly comprising a plurality of Y-axis motion control flexures.

In some example embodiments, the one or more position sensors each include: a plurality of position sensing fingers; and a plurality of position sensing recesses arranged in alignment with and configured to receive the plurality of position sensing fingers.

In some example embodiments, the plurality of position sensing fingers comprise X-axis position sensing fingers attached to the X-axis displacement assembly, and the plurality of position sensing recesses comprise X-axis position sensing recesses formed in the movable portion for receiving the X-axis position sensing fingers; and the plurality of position sensing fingers comprise Y-axis position sensing fingers attached to the Y-axis displacement assembly, and the plurality of position sensing recesses comprise Y-axis position sensing recesses formed in the stationary portion for receiving the Y-axis position sensing fingers.

In some example embodiments, the plurality of position sensing fingers at least partially overlap with the plurality of position sensing recesses, and the plurality of position sensing recesses have a curvature corresponding to a curvature of the plurality of position sensing fingers, respectively.

In some example embodiments, the stationary portion comprises a fixed outer frame, the movable portion has an optoelectronic device attached thereto, and the one or more positions sensors are configured to enable detection of changes in position of the movable portion in relation to the stationary portion, and the MEMS motion stage further includes: an actuator configured to generate controlled amounts of force in one or more directions for enabling an optical image stabilization (OIS) function for the optoelectronic device based on the changes in position of the movable portion in relation to the stationary portion.

According to another aspect, a multi-axis micro-electrical-mechanical system (MEMS) assembly is provided. The multi-axis MEMS assembly includes an optoelectronic device, and a MEMS motion stage as described above coupled to the optoelectronic device.

In some example embodiments, the optoelectronic device includes one or more of an image sensor and a lens assembly, and the MEMS motion stage includes an in-plane actuation subassembly configured to enable in-plane movement of the optoelectronic device for implementing optical image stabilization (OIS) according to feedback from the one or more position sensors.

According to yet another aspect, a micro-electrical-mechanical system (MEMS) image sensor assembly is provided. The MEMS image sensor assembly includes an image sensor subassembly including one or more image sensors, a lens assembly, and an in-plane MEMS motion stage subassembly coupled to the image sensor subassembly and the lens assembly, wherein the in-plane MEMS motion stage subassembly comprises the MEMS motion stage as described above.

In some example embodiments, the image sensor subassembly further includes one or more microcontrollers or processors configured to enable an optical image stabilization (OIS) function based on one or more signals or measurements obtained via the one or more position sensors, and the in-plane MEMS motion stage subassembly includes an in-plane actuation subassembly configured to generate controlled amounts of force in one or more directions to enable in-plane movement of one or more of the image sensor subassembly and the lens assembly for implementing the OIS function.

The details of one or more implementations are set forth in the accompanying drawings and the description below. Other features and advantages will become apparent from the description, the drawings, and the claims. It should be understood that all combinations of the foregoing concepts and additional concepts described in greater detail herein are contemplated as being part of the subject matter disclosure herein. For example, all combinations of claimed subject matter appearing at the end of this disclosure are contemplated as being part of the subject matter disclosed herein.

### BRIEF DESCRIPTION OF THE DRAWINGS

The embodiments of the present disclosure will be understood and appreciated more fully from the following description when taken in conjunction with the drawings, in which:

FIG. 1A is a perspective view of a MEMS camera module in accordance with various embodiments of the present disclosure;

FIG. 1B is a diagrammatic view of an in-plane MEMS actuator with an optoelectronic device in accordance with various embodiments of the present disclosure;

FIG. 1C is a perspective view of an in-plane MEMS actuator with the optoelectronic device in accordance with various embodiments of the present disclosure;

FIG. 2A is a diagrammatic view of an in-plane MEMS actuator in accordance with various embodiments of the present disclosure;

FIG. 2B is a diagrammatic view of a comb drive sector in accordance with various embodiments of the present disclosure;

FIG. 2C is a diagrammatic view of a comb pair in accordance with various embodiments of the present disclosure;

FIG. 2D is a diagrammatic view of fingers of the comb pair of FIG. 2C in accordance with various embodiments of the present disclosure;

FIG. 3A is a diagrammatic view of a MEMS package in accordance with various embodiments of the present disclosure;

FIGS. 3B-3D are diagrammatic views of a piezoelectric out-of-plane actuator in accordance with various embodiments of the present disclosure;

FIG. 3E is a diagrammatic view of a piezoelectric in-plane actuator in accordance with various embodiments of the present disclosure;

FIG. 4A is a diagrammatic view of a MEMS image sensor assembly in accordance with various embodiments of the present disclosure;

FIG. 4B is an exploded diagrammatic view of a MEMS image sensor assembly in accordance with various embodiments of the present disclosure;

FIG. 4C is a cross-sectional view of an electromagnetic actuator assembled as part of the MEMS image sensor assembly of FIGS. 4A-4B, with a magnetic flux graph imposed over the cross-section;

FIG. 5A is a diagrammatic view of an electrically-conductive, MEMS flexure assembly in an unlatched configuration in accordance with various embodiments of the present disclosure;

FIG. 5B is a diagrammatic view of an electrically-conductive, MEMS flexure assembly in a latched configuration in accordance with various embodiments of the present disclosure;

FIG. 5C is a diagrammatic view of a latch assembly of the electrically-conductive, MEMS flexure assembly of FIG. 5A in the unlatched configuration in accordance with various embodiments of the present disclosure;

FIG. 5D is a diagrammatic view of a latch assembly of the electrically-conductive, MEMS flexure assembly of FIG. 5B in the latched configuration in accordance with various embodiments of the present disclosure;

FIGS. 6A-6B are diagrammatic and perspective views, respectively, of an electrically-connected MEMS motion stage in a nominal position, in accordance with various embodiments of the present disclosure;

FIGS. 6C-6D are detail and perspective views, respectively, of motion control assemblies and position sensors of the electrically-connected MEMS motion stage of FIGS. 6A-6B in the nominal position, in accordance with various embodiments of the present disclosure;

FIGS. 7A-7B are diagrammatic and perspective views, respectively, of the electrically-connected MEMS motion stage in a negative Y position, in accordance with various embodiments of the present disclosure;

FIGS. 7C-7D are detail and perspective views, respectively, of motion control assemblies and position sensors of the electrically-connected MEMS motion stage of FIGS. 7A-7B in the negative Y position, in accordance with various embodiments of the present disclosure;

FIGS. 8A-8B are diagrammatic and perspective views, respectively, of the electrically-connected MEMS motion stage in a positive X position, in accordance with various embodiments of the present disclosure;

FIGS. 8C-8D are detail and perspective views, respectively, of motion control assemblies and position sensors of the electrically-connected MEMS motion stage of FIGS. 8A-8B in the positive X position, in accordance with various embodiments of the present disclosure;

FIGS. 8E-8F are detail and perspective views, respectively, of motion control assemblies and position sensors of the electrically-connected MEMS motion stage of FIGS. 8A-8B in the positive X position, in accordance with various embodiments of the present disclosure;

FIGS. 9A-9B are diagrammatic and perspective views, respectively, of the electrically-connected MEMS motion stage in a positive X and negative Y position, in accordance with various embodiments of the present disclosure;

FIGS. 9C-9D are detail and perspective views, respectively, of motion control assemblies and position sensors of the electrically-connected MEMS motion stage of FIGS. 9A-9B in the positive X and negative Y position, in accordance with various embodiments of the present disclosure; and

FIGS. 9E-9F are detail and perspective views, respectively, of motion control assemblies and position sensors of the electrically-connected MEMS motion stage of FIGS. 9A-9B in the positive X and negative Y position, in accordance with various embodiments of the present disclosure.

It should be appreciated that like reference symbols in the various drawings indicate like elements, except where otherwise indicated in the written description below.

### DETAILED DESCRIPTION

### System Overview

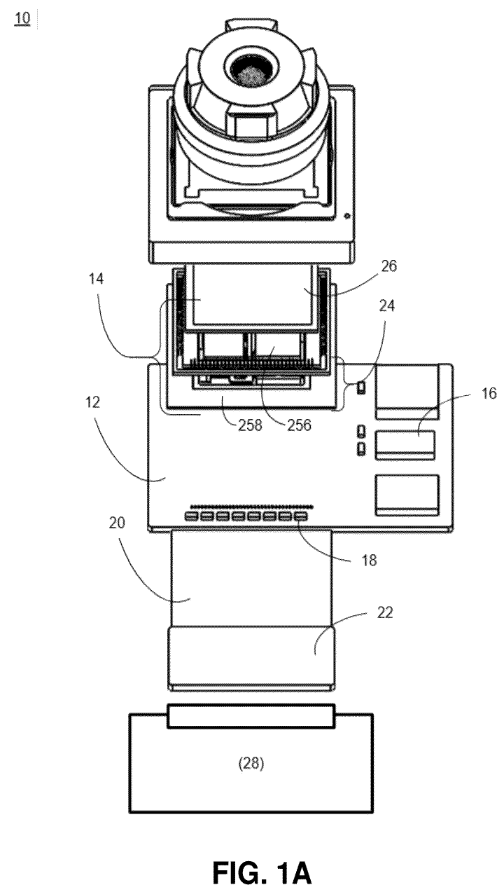

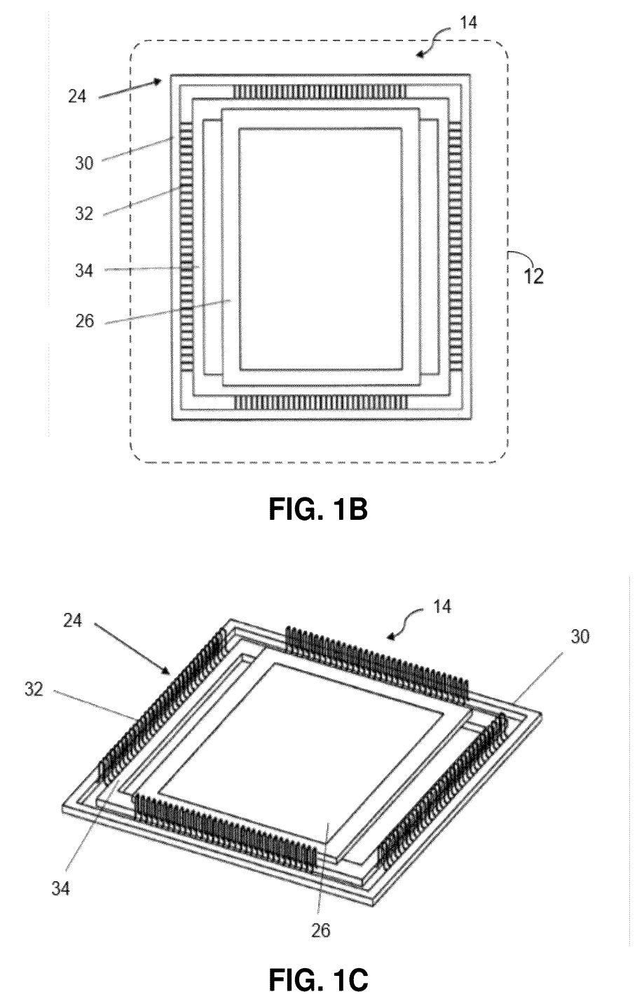

Referring to FIG. 1A, there is shown MEMS camera module 10, in accordance with various aspects of this disclosure. In this example, MEMS camera module 10 is shown to include printed circuit board 12, multi-axis MEMS assembly 14, driver circuits 16, electronic components 18, flexible circuit 20, and electrical connector 22. Multi-axis MEMS assembly 14 may include micro-electrical-mechanical system (MEMS) actuator 24 (configured to provide linear three-axis movement) and optoelectronic device 26 coupled to micro-electrical-mechanical system (MEMS) actuator 24.

As will be discussed below in greater detail, examples of micro-electrical-mechanical system (MEMS) actuator 24 may include but are not limited to an in-plane MEMS actuator, an out-of-plane MEMS actuator, and a combination in-plane/out-of-plane MEMS actuator. For example, and if micro-electrical-mechanical system (MEMS) actuator 24 is an in-plane MEMS actuator, the in-plane MEMS actuator may include an electrostatic comb drive actuation system (as will be discussed below in greater detail). Additionally, if micro-electrical-mechanical system (MEMS) actuator 24 is an out-of-plane MEMS actuator, the out-of-plane MEMS actuator may include a piezoelectric actuation system or electrostatic actuation system. And if micro-electrical-mechanical system (MEMS) actuator 24 is a hybrid in-plane/out-of-plane MEMS actuator, the combination in-plane/out-of-plane MEMS actuator may include an electrostatic comb drive actuation system and a piezoelectric actuation system.

As will be discussed below in greater detail, examples of optoelectronic device 26 may include but are not limited to an image sensor, a holder assembly, an IR filter and/or a lens assembly. Examples of electronic components 18 may include but are not limited to various electronic or semiconductor components and devices. Flexible circuit 20 and/or connector 22 may be configured to electrically couple MEMS camera module 10 to e.g., a smart phone or a digital camera (represented as generic item 28 in FIG. 1A).

In some embodiments, some of the components of MEMS camera module 10 may be joined together using various epoxies/adhesives. For example, an outer frame of micro-electrical-mechanical system (MEMS) actuator 24 may include contact pads that may correspond to similar contact pads on printed circuit board 12.

Referring also to FIG. 1B, there is shown multi-axis MEMS assembly 14, which may include optoelectronic device 26 coupled to micro-electrical-mechanical system (MEMS) actuator 24. As discussed above, examples of micro-electrical-mechanical system (MEMS) actuator 24 may include but are not limited to an in-plane MEMS actuator, an out-of-plane MEMS actuator, and a combination in-plane/out-of-plane MEMS actuator.

When configured to provide in-plane actuation functionality, micro-electrical-mechanical system (MEMS) actuator 24 may include outer frame 30, plurality of electrically conductive flexures 32, MEMS actuation core 34 for attaching a payload (e.g., a device), and attached optoelectronic device 26. Optoelectronic device 26 may be coupled to MEMS actuation core 34 of micro-electrical-mechanical system (MEMS) actuator 24 by epoxy (or various other adhesives/materials and/or bonding methods).

Referring also to FIG. 1C, a plurality of electrically conductive flexures 32 of micro-electrical-mechanical system (MEMS) actuator 24 may be curved upward and buckled to achieve the desired level of flexibility and compression. In the illustrated embodiment, the plurality of electrically conductive flexures 32 may have one end attached to MEMS actuation core 34 (e.g., the moving portion of micro-electrical-mechanical system (MEMS) actuator 24) and the other end attached to outer frame 30 (e.g., the fixed portion of micro-electrical-mechanical system (MEMS) actuator 24).

The plurality of electrically conductive flexures 32 may be conductive wires that may extend above the plane (e.g., an upper surface) of micro-electrical-mechanical system (MEMS) actuator 24 and may electrically couple laterally separated components of micro-electrical-mechanical system (MEMS) actuator 24. For example, the plurality of electrically conductive flexures 32 may provide electrical signals from optoelectronic device 26 and/or MEMS actuation core 34 to outer frame 30 of micro-electrical-mechanical system (MEMS) actuator 24. As discussed above, outer frame 30 of micro-electrical-mechanical system (MEMS) actuator 24 may be affixed to circuit board 12 using epoxy (or various other adhesive materials or devices).

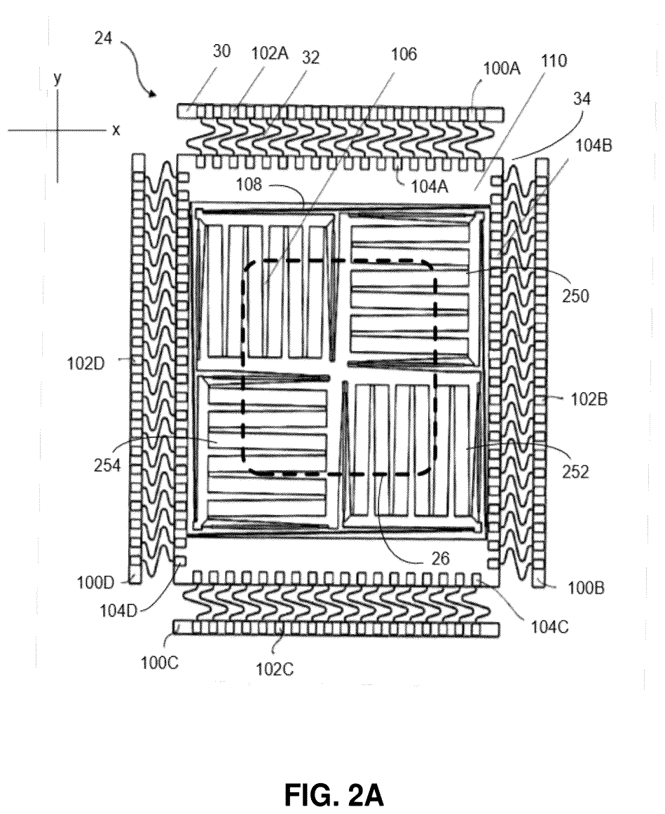

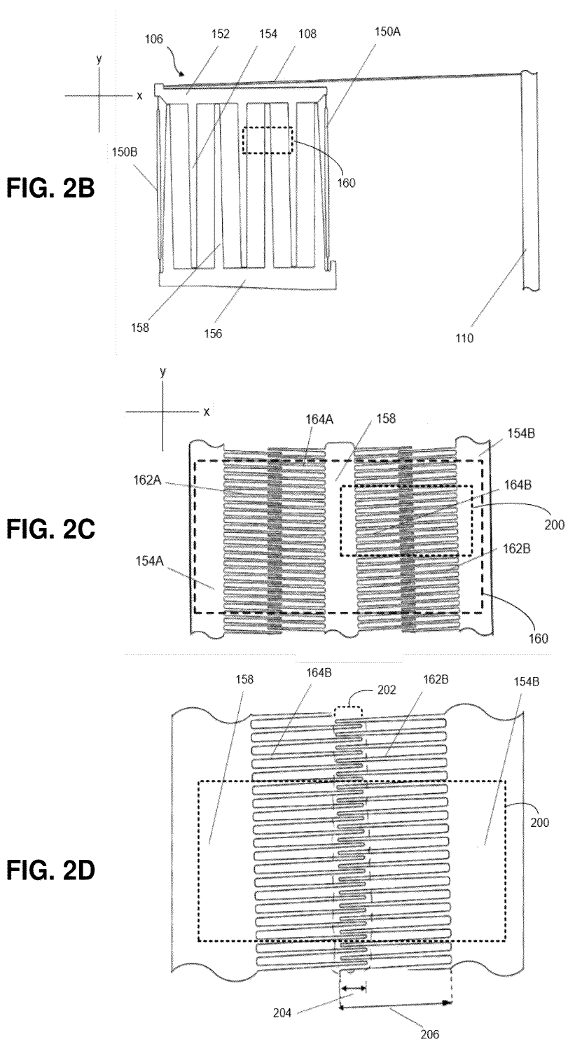

Referring also to FIG. 2A, there is shown a top view of micro-electrical-mechanical system (MEMS) actuator 24 in accordance with various embodiments of the disclosure. Outer frame 30 is shown to include (in this example) four frame assemblies (e.g., frame assembly 100A, frame assembly 100B, frame assembly 100C, frame assembly 100D) that are shown as being spaced apart to allow for additional detail.

Outer frame 30 of micro-electrical-mechanical system (MEMS) actuator 24 may include a plurality of contact pads (e.g., contact pads 102A on frame assembly 100A, contact pads 102B on frame assembly 100B, contact pads 102C on frame assembly 100C, and contact pads 102D on frame assembly 100D), which may be electrically coupled to one end of plurality of electrically conductive flexures 32. The curved shape of electrically conductive flexures 32 is provided for illustrative purposes only and, while illustrating one possible embodiment, other configurations are possible and are considered to be within the scope of this disclosure.

MEMS actuation core 34 may include a plurality of contact pads (e.g., contact pads 104A, contact pads 104B, contact pads 104C, contact pads 104D), which may be electrically coupled to the other end of the plurality of electrically conductive flexures 32. A portion of the contact pads (e.g., contact pads 104A, contact pads 104B, contact pads 104C, contact pads 104D) of MEMS actuation core 34 may be electrically coupled to optoelectronic device 26 by wire bonding, silver paste, or eutectic seal, thus allowing for the electrical coupling of optoelectronic device 26 to outer frame 30.

### Electrostatic Actuation

MEMS actuation core 34 may include one or more comb drive sectors (e.g., comb drive sector 106) that are actuation sectors disposed within micro-electrical-mechanical system (MEMS) actuator 24. The comb drive sectors (e.g., comb drive sector 106) within MEMS actuation core 34 may be disposed in the same plane and may be positioned orthogonal to each other to allow for movement in two axes (e.g., the X-axis and the Y-axis). Accordingly, the in-plane MEMS actuator generally (and MEMS actuation core 34 specifically) may be configured to provide linear X-axis movement and linear Y-axis movement.

While MEMS actuation core 34 is shown to include four comb drive sectors in the particular example shown in FIG. 2A, this is for illustrative purposes only and is not intended to be a limitation of this disclosure, as other configurations are possible. For example, the number of comb drive sectors may be increased or decreased depending upon design criteria.

While the four comb drive sectors are shown to be generally square in shape in the particular example shown in FIG. 2A, this is for illustrative purposes only and is not intended to be a limitation of this disclosure, as other configurations are possible. For example, the shape of the comb drive sectors may be changed to meet various design criteria.

While the comb drive sectors (e.g., comb drive sector 106) within MEMS actuation core 34 are shown to be positioned orthogonal to each other to allow for movement in two axes (e.g., the X-axis and the Y-axis) in the particular example of FIG. 2A, this is for illustrative purposes only and is not intended to be a limitation of this disclosure, as other configurations are possible. For example, the comb drive sectors (e.g., comb drive sector 106) within MEMS actuation core 34 may be positioned parallel to each other to allow for movement in a single axis (e.g., either the X-axis or the Y-axis).

Each comb drive sector (e.g., comb drive sector 106) within MEMS actuation core 34 may include one or more moving portions and one or more fixed portions. As will be discussed below in greater detail, a comb drive sector (e.g., comb drive sector 106) within MEMS actuation core 34 may be coupled, via a cantilever assembly (e.g., cantilever assembly 108), to outer periphery 110 of MEMS actuation core 34 (i.e., the portion of MEMS actuation core 34 that includes contact pads 104A, contact pads 104B, contact pads 104C, contact pads 104D), which is the portion of MEMS actuation core 34 to which optoelectronic device 26 may be coupled, thus effectuating the transfer of movement to optoelectronic device 26.

Referring also to FIG. 2B, there is shown a top view of comb drive sector 106 in accordance with various embodiments of the present disclosure. Each comb drive sector (e.g., comb drive sector 106) may include one or more motion control cantilever assemblies (e.g., motion control cantilever assemblies 150A, 150B) positioned outside of comb drive sector 106, moveable frame 152, moveable spines 154, fixed frame 156, fixed spines 158, and cantilever assembly 108 that is configured to couple moving frame 152 to outer periphery 110 of MEMS actuation core 34. In this particular configuration, motion control cantilever assemblies 150A, 150B may be configured to prevent Y-axis displacement between moving frame 152/moveable spines 154 and fixed frame 156/fixed spines 158.

Comb drive sector 106 may include a movable member including moveable frame 152 and multiple moveable spines 154 that are generally orthogonal to moveable frame 152. Comb drive sector 106 may also include a fixed member including fixed frame 156 and multiple fixed spines 158 that are generally orthogonal to fixed frame 156. Cantilever assembly 108 may be deformable in one direction (e.g., in response to Y-axis deflective loads) and rigid in another direction (e.g., in response to X-axis tension and compression loads), thus allowing for cantilever assembly 108 to absorb motion in the Y-axis but transfer motion in the X-axis.

Referring also to FIG. 2C, there is shown a detail view of portion 160 of comb drive sector 106 of FIG. 2B. Moveable spines 154A, 154B may include a plurality of discrete moveable actuation fingers that are generally orthogonally-attached to moveable spines 154A, 154B. For example, moveable spine 154A is shown to include moveable actuation fingers 162A and moveable spine 154B is shown to include moveable actuation fingers 162B.

Further, fixed spine 158 may include a plurality of discrete fixed actuation fingers that are generally orthogonally-attached to fixed spine 158. For example, fixed spine 158 is shown to include fixed actuation fingers 164A that are configured to mesh and interact with moveable actuation fingers 162A. Further, fixed spine 158 is shown to include fixed actuation fingers 164B that are configured to mesh and interact with moveable actuation fingers 162B.

Accordingly, various numbers of actuation fingers may be associated with (i.e., coupled to) the moveable spines (e.g., moveable spines 154A, 154B) and/or the fixed spines (e.g., fixed spine 158) of comb drive sector 106. As discussed above, each comb drive sector (e.g., comb drive sector 106) may include two motion control cantilever assemblies 150A, 150B separately placed on each side of comb drive sector 106. Each of the two motion control cantilever assemblies 150A, 150B may be configured to couple moveable frame 152 and fixed frame 156, as this configuration enables moveable actuation fingers 162A, 162B to be displaceable in the X-axis with respect to fixed actuation fingers 164A, 164B (respectively) while preventing moveable actuation fingers 162A, 162B from being displaced in the Y-axis and contacting fixed actuation fingers 164A, 164B (respectively).

While actuation fingers 162A, 162B, 164A, 164B (or at least the center axes of actuation fingers 162A, 162B, 164A, 164B) are shown to be generally parallel to one another and generally orthogonal to the respective spines to which they are coupled, this is for illustrative purposes only and is not intended to be a limitation of this disclosure, as other configurations are possible. Further and in some embodiments, actuation fingers 162A, 162B, 164A, 164B may have the same width throughout their length and in other embodiments, actuation fingers 162A, 162B, 164A, 164B may be tapered.

Further and in some embodiments, moveable frame 152 may be displaced in the positive X-axis direction when a voltage potential is applied between actuation fingers 162A and actuation fingers 164A, while moveable frame 152 may be displaced in the negative X-axis direction when a voltage potential is applied between actuation fingers 162B and actuation fingers 164B.

Referring also to FIG. 2D, there is shown a detail view of portion 200 of comb drive sector 106 of FIG. 2C. Fixed spine 158 may be generally parallel to moveable spine 154B, wherein actuation fingers 164B and actuation fingers 162B may overlap within a region (e.g., overlap region 202), wherein the width of the region (e.g., overlap region 202) is typically in the range of 10-50 microns. While overlap region 202 is described as being in the range of 10-50 microns in this particular example, this is for illustrative purposes only and is not intended to be a limitation of this disclosure, as other configurations are possible.

Overlap region 202 may represent the distance 204 where the ends of actuation fingers 162B extends past and overlap the ends of actuation fingers 164B, which are interposed therebetween. In some embodiments, actuation fingers 162B and actuation fingers 164B may be tapered such that their respective tips are narrower than their respective bases (i.e., where they are attached to their spines). Various degrees of taper may be utilized with respect to actuation fingers 162B and actuation fingers 164B. Additionally, the overlap of actuation fingers 162B and actuation fingers 164B provided by overlap region 202 may help ensure that there is sufficient initial actuation force when an electrical voltage potential is applied, so that MEMS actuation core 34 may move gradually and smoothly without any sudden jumps when varying the applied voltage. The height of actuation fingers 162B and actuation fingers 164B may be determined by various aspects of the MEMS fabrication process and various design criteria.

Length 206 of actuation fingers 162B and actuation fingers 164B, the size of overlap region 202, the gaps between adjacent actuation fingers, and actuation finger taper angles that are incorporated into various embodiments may be determined by various design criteria, application considerations, and manufacturability considerations, wherein these measurements may be optimized to achieve the required displacement utilizing the available voltage potential.

As shown in FIG. 2A and as discussed above, MEMS actuation core 34 may include one or more comb drive sectors (e.g., comb drive sector 106), wherein the comb drive sectors (e.g., comb drive sector 106) within MEMS actuation core 34 may be disposed in the same plane and may be positioned orthogonal to each other to allow for movement in two axes (e.g., the X-axis and the Y-axis).

Specifically, and in this particular example, MEMS actuation core 34 is shown to include four comb drive sectors (e.g., comb drive sectors 106, 250, 252, 254). As discussed above, comb drive sector 106 is configured to allow for movement along the X-axis, while preventing movement along the Y-axis. As comb drive sector 252 is similarly configured, comb drive sector 252 may allow for movement along the X-axis, while preventing movement along the Y-axis. Accordingly, if a signal is applied to comb drive sector 106 that provides for positive X-axis movement, while a signal is applied to comb drive sector 252 that provides for negative X-axis movement, actuation core 34 may be displaced in a clockwise direction. Conversely, if a signal is applied to comb drive sector 106 that provides for negative X-axis movement, while a signal is applied to comb drive sector 252 that provides for positive X-axis movement, actuation core 34 may be displaced in a counterclockwise direction.

Further, comb drive sectors 250, 254 are configured (in this example) to be orthogonal to comb drive sectors 106, 252. Accordingly, comb drive sectors 250, 254 may be configured to allow for movement along the Y-axis, while preventing movement along the X-axis. Accordingly, if a signal is applied to comb drive sector 250 that provides for positive Y-axis movement, while a signal is applied to comb drive sector 254 that provides for negative Y-axis movement, actuation core 34 may be displaced in a counterclockwise direction. Conversely, if a signal is applied to comb drive sector 250 that provides for negative Y-axis movement, while a signal is applied to comb drive sector 254 that provides for positive Y-axis movement, actuation core 34 may be displaced in a clockwise direction.

Accordingly, the in-plane MEMS actuator (e.g., micro-electrical-mechanical system (MEMS) actuator 24) generally, and MEMS actuation core 34 more specifically, may be configured to provide rotational (e.g., clockwise or counterclockwise) Z-axis movement of the payload (e.g., optoelectronic device 26).

### Piezoelectric Actuation

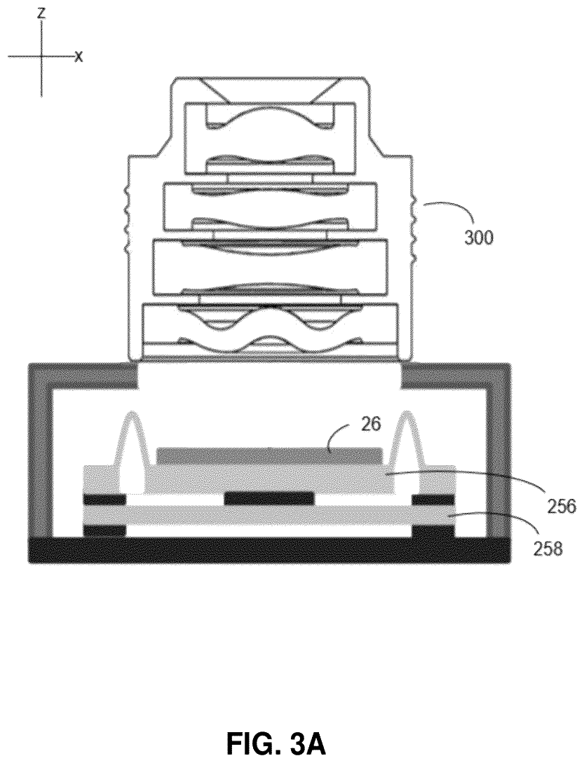

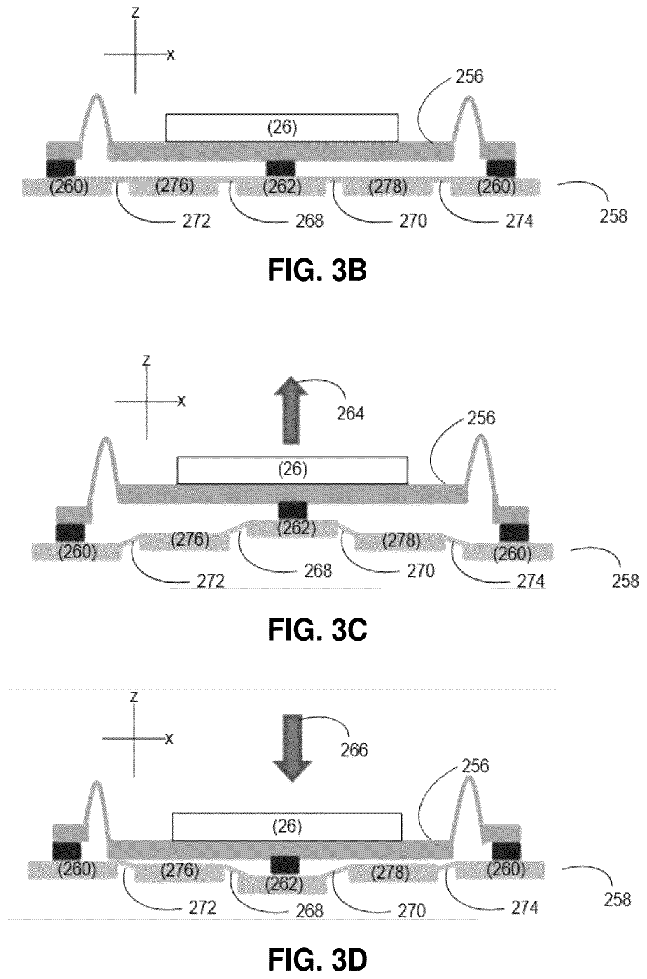

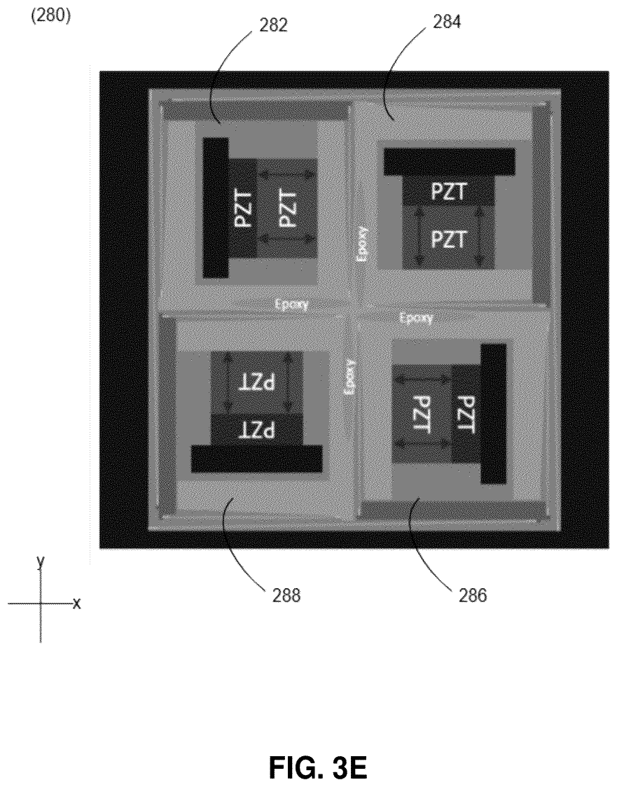

As stated above, examples of micro-electrical-mechanical system (MEMS) actuator 24 may include but are not limited to an in-plane MEMS actuator, an out-of-plane MEMS actuator, and a combination in-plane/out-of-plane MEMS actuator. For example, and referring also to FIG. 3A and FIGS. 3B-3D, micro-electrical-mechanical system (MEMS) actuator 24 is shown to include an in-plane MEMS actuator (e.g., in-plane MEMS actuator 256) and an out-of-plane MEMS actuator (e.g., out-of-plane MEMS actuator 258), wherein FIGS. 2A-2D illustrate one possible embodiment of in-plane MEMS actuator 256. Optoelectronic device 26 may be coupled to in-plane MEMS actuator 256, and in-plane MEMS actuator 256 may be coupled to out-of-plane MEMS actuator 258.

An example of in-plane MEMS actuator 256 may include, but is not limited to, an optical image stabilization (OIS) actuator. As is known in the art, optical image stabilization is a family of techniques that reduce blurring associated with the motion of a camera or other imaging device during exposure. Generally, OIS technology compensates for pan and tilt (angular movement, equivalent to yaw and pitch) of the imaging device, though electronic image stabilization may also compensate for rotation. Optical image stabilization may be used in image-stabilized binoculars, still and video cameras, astronomical telescopes, and smartphones. With still cameras, camera shake may be a particular problem at slow shutter speeds or with long focal length (telephoto or zoom) lenses. With video cameras, camera shake may cause visible frame-to-frame jitter in the recorded video. In astronomy, the problem may be amplified by variations in the atmosphere (which changes the apparent positions of objects over time).

An example of out-of-plane MEMS actuator 258 may include, but is not limited to, an autofocus (AF) actuator. As is known in the art, an autofocus system may use a sensor, a control system, and an actuator to focus on an automatically (or manually) selected area. Autofocus methodologies may be distinguished by their type (e.g., active, passive or hybrid). Autofocus systems may rely on one or more sensors to determine correct focus, wherein some autofocus systems may rely on a single sensor while others may use an array of sensors.

FIG. 3A shows lens assembly 300 with in-plane MEMS actuator 256 and out-of-plane MEMS actuator 258 according to an example embodiment. FIGS. 3B, 3C, and 3D show one possible embodiment of out-of-plane MEMS actuator 258 in various states of activation/excitation, respectively. Referring to FIGS. 3B-3D, out-of-plane MEMS actuator 258 may include frame 260 (a rigid frame assembly which is configured to be stationary) and moveable stage 262, wherein out-of-plane MEMS actuator 258 may be configured to provide linear Z-axis movement. For example, out-of-plane MEMS actuator 258 may include a multi-morph piezoelectric actuator that may be selectively and controllably deformable when an electrical charge is applied, wherein the polarity of the applied electrical charge may vary the direction in which the multi-morph piezoelectric actuator (i.e., out-of-plane MEMS actuator 258) is deformed. For example, FIG. 3B shows out-of-plane MEMS actuator 258 in a natural position without an electrical charge being applied. Further, FIG. 3C shows out-of-plane MEMS actuator 258 in an extended position (i.e., displaced in the direction of arrow 264) with an electrical charge having a first polarity being applied, while FIG. 3D shows out-of-plane MEMS actuator 258 in a retracted position (i.e., displaced in the direction of arrow 266) with an electrical charge having an opposite polarity being applied.

As discussed above, the multi-morph piezoelectric actuator (i.e., out-of-plane MEMS actuator 258) may be deformable by applying an electrical charge. To accomplish such deformability that allows for such linear Z-axis movement, the multi-morph piezoelectric actuator (i.e., out-of-plane MEMS actuator 258) may include a bending piezoelectric actuator, for example.

As discussed above, the multi-morph piezoelectric actuator (i.e., out-of-plane MEMS actuator 258) may include rigid frame assembly 260 (which is configured to be stationary) and moveable stage 262 that may be configured to be affixed to in-plane MEMS actuator 256. As discussed above, optoelectronic device 26 may be coupled to in-plane MEMS actuator 256, and in-plane MEMS actuator 256 may be coupled to out-of-plane MEMS actuator 258. Accordingly, and when out-of-plane MEMS actuator 258 is in an extended position (i.e., displaced in the direction of arrow 264) with an electrical charge having a first polarity being applied (as shown in FIG. 3C), optoelectronic device 26 may be displaced in the positive z-axis direction and towards a lens assembly (e.g., lens assembly 300 of FIG. 3A). Alternatively, and when out-of-plane MEMS actuator 258 is in a retracted position (i.e., displaced in the direction of arrow 266) with an electrical charge having an opposite polarity being applied (as shown in FIG. 3D), optoelectronic device 26 may be displaced in the negative z-axis direction and away from a lens assembly (e.g., lens assembly 300 of FIG. 3A). Accordingly, and by displacing optoelectronic device 26 in the z-axis with respect to a lens assembly (e.g., lens assembly 300 of FIG. 3A), autofocus functionality may be achieved.

The multi-morph piezoelectric actuator (i.e., out-of-plane MEMS actuator 258) may include at least one deformable piezoelectric portion (e.g., deformable piezoelectric portions 268, 270, 272, 274) configured to couple moveable stage 262 to rigid frame assembly 260.

For example, and in one particular embodiment, multi-morph piezoelectric actuator (i.e., out-of-plane MEMS actuator 258) may include a rigid intermediate stage (e.g., rigid intermediate stages 276, 278). A first deformable piezoelectric portion (e.g., deformable piezoelectric portions 268, 270) may be configured to couple rigid intermediate stage (e.g., rigid intermediate stages 276, 278) to moveable stage 262, and a second deformable piezoelectric portion (e.g., deformable piezoelectric portions 272, 274) may be configured to couple the rigid intermediate stage (e.g., rigid intermediate stages 276, 278) to rigid frame assembly 260.

Linear Z-axis (i.e., out-of-plane) movement of moveable stage 262 of out-of-plane MEMS actuator 258 may be generated due to the deformation of the deformable piezoelectric portion (e.g., deformable piezoelectric portions 268, 270, 272, 274), which may be formed of a piezoelectric material (e.g., PZT (lead zirconate titanate), zinc oxide, or other suitable material) that may be configured to deflect in response to an electrical signal. As is known in the art, piezoelectric materials are a special type of ceramic that expands or contracts when an electrical field is applied, thus generating motion and force.

While out-of-plane MEMS actuator 258 is described above as including a single moveable stage (e.g., moveable stage 262) that enables linear movement in the Z-axis, this is for illustrative purposes only and is not intended to be a limitation of this disclosure, as other configurations are possible and are considered to be within the scope of this disclosure. For example, out-of-plane MEMS actuator 258 may be configured to include multiple moveable stages. For example, if deformable piezoelectric portions 272, 274 were configured to be separately controllable, additional degrees of freedom (such as tip and/or tilt) may be achievable. For example and in such a configuration, displacing intermediate stage 276 in an upward direction (i.e., in the direction of arrow 264) while displacing intermediate stage 278 in a downward direction (i.e., in the direction of arrow 266) would result in clockwise rotation of optoelectronic device 26 about the Y-axis, while displacing intermediate stage 276 in a downward direction (i.e., in the direction of arrow 266) while displacing intermediate stage 278 in a upward direction (i.e., in the direction of arrow 264) would result in counterclockwise rotation of optoelectronic device 26 about the Y-axis. Additionally or alternatively, corresponding clockwise and counterclockwise rotation of optoelectronic device 26 about the X-axis may be achieved via additional/alternative intermediate stages.

While FIGS. 3B-3D each show one possible embodiment of an out-of-plane piezoelectric MEMS actuator in various states of activation/excitation, respectively, this is for illustrative purposes only and is not intended to be a limitation of this disclosure, as other configurations are possible and are considered to be within the scope of this disclosure. For example, and as shown in FIG. 3E, an in-plane piezoelectric MEMS actuator 280 may be formed in a fashion similar to that of the above-described in-plane electrostatic MEMS actuators. Accordingly, in-plane piezoelectric MEMS actuator 280 may include a plurality of piezoelectric drive sectors (e.g., piezoelectric drive sectors 282, 284, 286, 288) configured in a similar orthogonal fashion (e.g., piezoelectric drive sectors 282, 286 being configured to enable movement in one axis and piezoelectric drive sectors 284, 288 being configured to enable movement in an orthogonal axis), thus enabling movement in the X-axis and the Y-axis, and rotation about the Z-axis, for moving the payload (e.g., optoelectronic device 26).

### MEMS Image Sensor Assembly

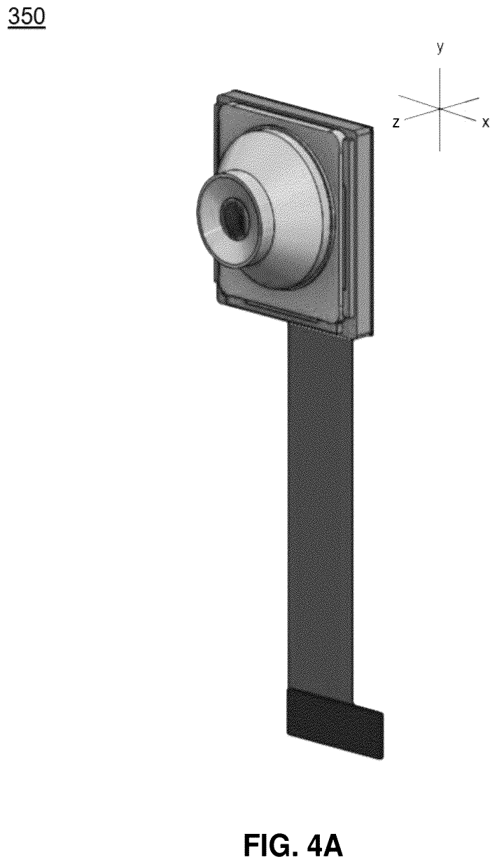

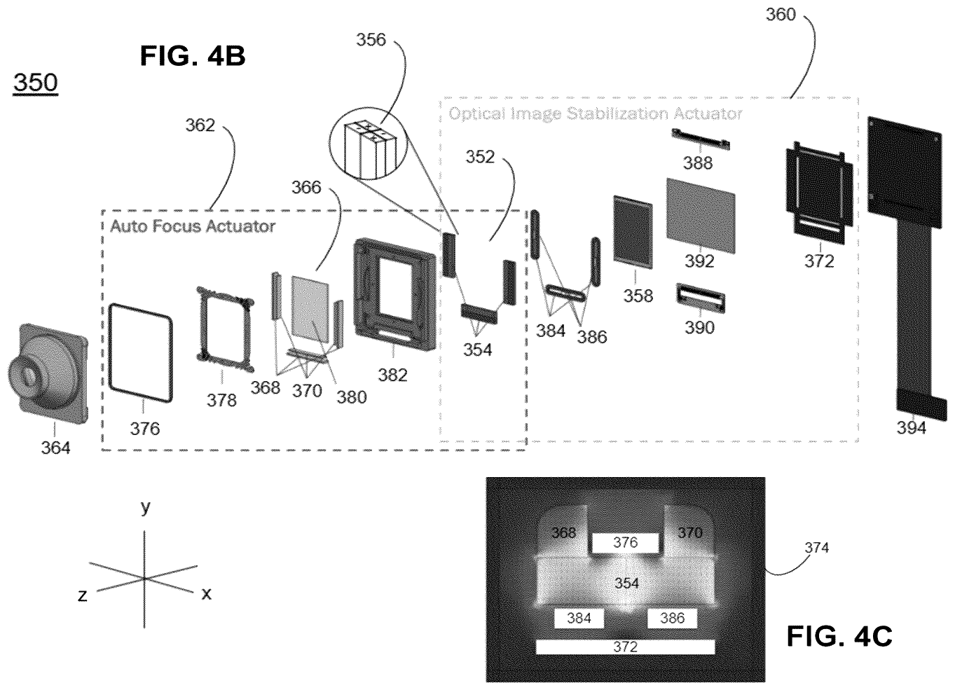

Referring also to FIG. 4A and FIG. 4B, there is shown a MEMS image sensor assembly (e.g., MEMS image sensor assembly 350). MEMS image sensor assembly 350 may include a common magnet assembly (e.g., common magnet assembly 352). In this particular example, common magnet assembly 352 is referred to as being “common” because it is utilized to effectuate both in-plane and out-of-plane movement.

In the context of MEMS devices (e.g., MEMS image sensor assembly 350), “in-plane” and “out-of-plane” movements refer to different directions of motion within the device (e.g., MEMS image sensor assembly 350). These terms describe how components or structures within the MEMS device (e.g., MEMS image sensor assembly 350) can move relative to the device's substrate or plane. The following is an explanation of the differences between in-plane movement and out-of-plane movement:
1. In-Plane Movement:
   Definition: In-plane movement refers to motion that occurs within the same plane or surface as the device's substrate. It is motion along the X and Y axes, or lateral motion.
   Example: If you have a MEMS accelerometer on a chip, in-plane movement might involve the tiny sensing mass moving horizontally (left-right or up-down) within the same plane as the chip's surface to detect acceleration.
2. Out-of-Plane Movement:
   Definition: Out-of-plane movement, also known as vertical or Z-axis movement, refers to motion that occurs perpendicular to the device's substrate or plane. It is motion along the Z-axis, which is often considered the direction coming out of the plane of the chip.
   Example: In a MEMS micro-mirror device used in optical applications, out-of-plane movement involves the mirror tilting or rotating vertically away from or towards the substrate to redirect light beams.

To illustrate the difference, imagine you have a MEMS device (e.g., MEMS image sensor assembly 350) on a flat chip, such as a tiny mechanical component. If this component moves side to side or up and down on the same plane as the chip's surface, that is considered in-plane movement. If this component moves away from or towards the surface, perpendicular to the chip's plane, that is considered out-of-plane movement. Both types of movement have their applications in MEMS devices, and they can be used for various purposes, such as sensing, actuation, or manipulation of physical phenomena, for example. MEMS technology enables precise control of these movements, making it valuable in a wide range of industries, including electronics, sensors, medical devices, and more.

Referring to FIG. 4B, the common magnet assembly (e.g., common magnet assembly 352) may include a plurality of magnet assemblies (e.g., plurality of magnet assemblies 354). Examples of the plurality of magnet assemblies (e.g., plurality of magnet assemblies 354) may include a plurality of permanent magnet assemblies.

A permanent magnet is a type of magnet that retains its magnetic properties and generates a magnetic field without the need for an external power source, such as electricity. Unlike electromagnets, which require an electric current to create a magnetic field, permanent magnets are made from materials that have inherent magnetic properties.

Key characteristics of permanent magnets include:
Stability: Permanent magnets maintain their magnetic properties over an extended period, provided they are not subjected to conditions that could weaken or demagnetize them.
Magnetic Field: They generate a magnetic field that has north and south poles, and they exert attractive or repulsive forces on other magnetic materials or objects, depending on their orientation.
Materials: Permanent magnets are typically made from specific materials known as ferromagnetic materials, which include substances like iron, nickel, cobalt, and certain alloys.
Applications: Permanent magnets are used in various applications, such as electric motors, generators, magnetic locks, compasses, speakers, MRI machines, magnetic sensors, and more.
Shapes and Types: Permanent magnets can come in various shapes and forms, including bar magnets, horseshoe magnets, ring magnets, and more. They can also be categorized into different types, such as neodymium magnets (strongest commercially available magnets), ferrite magnets (ceramic magnets), and alnico magnets (aluminum, nickel, and cobalt alloys).
Magnetization: The process of creating a permanent magnet involves exposing the material to a strong external magnetic field or striking it while in a magnetic field. This aligns the magnetic domains within the material, creating a permanent magnet.
Demagnetization: While permanent magnets are relatively stable, they can be demagnetized or weakened if exposed to extreme heat, physical shock, or strong opposing magnetic fields.

Permanent magnets are integral to many technologies and devices that rely on magnetic interactions, and they play a crucial role in the functioning of various everyday items and industrial equipment. Their ability to generate a constant magnetic field without the need for an external power source makes them highly valuable in a wide range of applications.

The plurality of magnet assemblies (e.g., the plurality of magnet assemblies 354) may include a plurality of laminated magnet assemblies. For example, each of the plurality of magnet assemblies (e.g., plurality of magnet assemblies 354) may actually include multiple magnets that are positioned proximate and/or laminated to each other to form a plurality of magnet assemblies that form grid of magnetic poles 356.

MEMS image sensor assembly 350 may include an image sensor subassembly (e.g., image sensor subassembly 358). An example of an image sensor subassembly (e.g., image sensor subassembly 358) may include an optoelectronic device.

An image sensor subassembly (e.g., image sensor subassembly 358) refers to a component or module within a digital imaging system, such as a camera or a scanner, that includes one or more image sensors and associated components. Image sensor subassemblies are critical to the functioning of these devices as they are responsible for capturing and converting light or optical information into digital signals.

Some key components typically found in an image sensor subassembly include:
Image Sensor: The core component is the image sensor itself. This can be a CCD (Charge-Coupled Device) sensor, CMOS (Complementary Metal-Oxide-Semiconductor) sensor, or other specialized sensor types. The image sensor captures incoming light and converts it into an electrical signal.
Filter and Color Processing: In many image sensor subassemblies, filters are used to control the wavelengths of light that reach the sensor. This can include color filters for capturing RGB (Red, Green, Blue) information or specialized filters for specific applications, such as infrared or ultraviolet imaging.
Signal Processing Electronics: The subassembly may include electronics for amplifying, processing, and digitizing the electrical signals generated by the image sensor. This is essential for converting analog light information into digital image data.
Microcontrollers or Processors: In more advanced image sensor subassemblies, there may be microcontrollers or processors that handle various tasks, such as image signal processing, autofocus, exposure control, and optical image stabilization (OIS).
Mounting and Housing: These components are used to securely hold the image sensor and other elements in place within the device's overall structure.
Connectors: Image sensor subassemblies typically have connectors that allow them to interface with the rest of the imaging system or device, including data transfer and power connections.

Image sensor subassemblies (e.g., image sensor subassembly 358) can vary significantly in complexity and features, depending on the intended use and the sophistication of the imaging system. For instance, a smartphone camera module contains a relatively compact image sensor subassembly, while a high-end digital camera may have a more intricate and modular subassembly with interchangeable lenses.

MEMS image sensor assembly 350 may include an in-plane actuation subassembly (e.g., in-plane actuation subassembly 360) that utilizes the common magnet assembly (e.g., common magnet assembly 352) to effectuate in-plane movement of the image sensor subassembly (e.g., image sensor subassembly 358) and/or a lens assembly (e.g., lens assembly 364 to be discussed below in greater detail).

The in-plane actuation subassembly (e.g., in-plane actuation subassembly 360) may be an optical image stabilization (OIS) subassembly. An optical image stabilization (OIS) subassembly (e.g., in-plane actuation subassembly 360) is a key component of the camera system that is designed to reduce the blurriness and shakiness in photos and videos caused by hand tremors or movements when taking pictures or recording videos with a mobile phone (e.g., represented as generic item 28 in FIG. 1A). Optical image stabilization technology helps improve the overall image and video quality by compensating for these unintentional movements.

The primary components and features of an optical image stabilization (OIS) subassembly in a cellphone (represented as generic item 28) include:
Gyroscopic Sensors or Accelerometers: These sensors are integrated into the phone (represented as generic item 28) to detect any angular or linear movements or vibrations of the device during photography or video recording.
Actuators or Motors: OIS assemblies include small, precise motors or actuators that physically move the camera lens or image sensor to counteract the detected motion.
Feedback Loop: OIS systems operate within a feedback loop that continuously receives data from the sensors, evaluates the camera's movement, and calculates the necessary adjustments to stabilize the image or video.
Lens or Sensor Movement: In response to the sensor data, the OIS assembly shifts the camera lens or image sensor slightly to compensate for the detected motion. These movements can occur in multiple directions (typically pitch and yaw) to address various types of motion.
Control Circuitry and Algorithms: The cellphone's electronics and control algorithms are responsible for processing data from the sensors and orchestrating the adjustments required to maintain image stability.
Real-time Correction: OIS adjustments occur in real-time as you capture images or record videos, ensuring that the final output is as steady and sharp as possible.

The main benefits of optical image stabilization in a cellphone camera include:
Reduced Blurriness: OIS significantly reduces the blur in photos and videos, leading to sharper and clearer results.
Enhanced Low-Light Performance: OIS allows for longer exposure times in low-light conditions, resulting in better image quality without blur.
Smoother Video Recording: OIS is particularly useful for recording smooth and steady videos, as it minimizes the shakiness often associated with handheld recording.
Improved Overall Image Quality: Whether taking photos or recording videos, OIS contributes to better image quality by compensating for motion-induced imperfections.

The presence and effectiveness of optical image stabilization can vary among different cellphone models. High-end and flagship smartphones typically feature more advanced OIS systems, while budget or mid-range phones may have simpler implementations. OIS has become a standard feature in many modern smartphones, enhancing the overall photography and videography experience for users.

MEMS image sensor assembly 350 may include an out-of-plane actuation subassembly (e.g., out-of-plane actuation subassembly 362) that utilizes the common magnet assembly (e.g., common magnet assembly 352) to effectuate out-of-plane movement of the image sensor subassembly (e.g., image sensor subassembly 362) and/or the lens assembly (e.g., lens assembly 364 to be discussed below in greater detail).

The out-of-plane actuation subassembly (e.g., out-of-plane actuation subassembly 362) may be an autofocus (AF) subassembly. An autofocus (AF) subassembly (e.g., out-of-plane actuation subassembly 362) refers to the components and mechanisms responsible for automatically adjusting the focus of the phone's camera to capture sharp and clear images or videos. Most modern smartphones (represented as generic item 28) are equipped with sophisticated autofocus systems to make it easier for users to take high-quality photos and videos without the need for manual focus adjustments.

An autofocus (AF) assembly in a cell phone (represented as generic item 28) typically includes:
Focus Motor: Smartphones use small electric motors or actuators that can physically move the camera lens or the image sensor to achieve focus. Depending on the phone's design, this motor may be voice coil autofocus (VCM) or piezoelectric-based, among others.
Image Sensor: In many smartphones, the entire image sensor or a specific part of it can be moved to adjust the focus. This is known as sensor-based autofocus or sensor-shift autofocus.
Control Electronics: The phone's processor and control algorithms play a crucial role in determining when and how to adjust the focus. These algorithms analyze image data to assess focus accuracy.
Focus Sensors: Some smartphones use dedicated sensors, such as phase-detection or laser autofocus sensors, to measure the focus accuracy. These sensors help the system quickly and accurately determine the correct focus point, especially in challenging lighting conditions.
Focus Modes: Cell phones (represented as generic item 28) often provide various focus modes, such as single-shot autofocus (focuses once and locks the focus until a new command is given), continuous autofocus (keeps adjusting focus for moving subjects), or even manual focus control through the touchscreen interface.
Feedback Mechanism: A feedback loop continuously evaluates the image's focus quality and makes fine adjustments as needed until the subject is sharp.
Software Enhancements: Smartphone cameras also use software enhancements, such as face detection, object tracking, and scene recognition, to optimize focus for different shooting scenarios.

The autofocus (AF) assembly in a cell phone (represented as generic item 28) is essential for capturing high-quality photos and videos effortlessly. It allows users to focus on framing and composition without the need to manually adjust focus settings. The sophistication of the autofocus system can vary between smartphone models, with flagship phones often featuring more advanced and faster autofocus mechanisms, which is particularly useful for capturing fast-moving subjects or shooting in challenging lighting conditions.

As referenced above, MEMS image sensor assembly 350 may include a lens assembly (e.g., lens assembly 364) positioned proximate the image sensor subassembly (e.g., image sensor subassembly 358).

A lens assembly (e.g., lens assembly 364) in a cell phone, often referred to as a camera lens module or camera module, is a key component of the smartphone's camera system. It plays a crucial role in capturing photos and videos by focusing light onto the image sensor (e.g., image sensor subassembly 358), thereby creating a clear and sharp image. The lens assembly (e.g., lens assembly 364) is responsible for controlling various aspects of the photographic process, including focus, aperture, and image quality.

The main components and functions of a lens assembly in a cell phone typically include:
Lens Elements: The lens assembly typically includes multiple lens elements made of glass or specialized optical materials. These lens elements are arranged to bend and direct incoming light onto the image sensor. The combination and arrangement of these elements affect the camera's field of view, depth of field, and image quality.
Aperture Mechanism: Many cell phone camera lens assemblies incorporate an adjustable aperture mechanism. The aperture controls the amount of light that enters the camera, which in turn affects exposure and depth of field. A wider aperture (lower f-number) allows more light in and is useful for low-light conditions, while a narrower aperture (higher f-number) provides greater depth of field.
Focus Mechanism: The lens assembly contains components for focusing, either manually or automatically. Autofocus systems use tiny motors to adjust the position of the lens elements or the entire lens assembly to achieve precise focus on the subject. Some lens assemblies also support optical image stabilization (OIS) to reduce blurriness caused by hand tremors or motion.
Image Quality Enhancements: Many lens assemblies include coatings or technologies to improve image quality, such as anti-reflective coatings to reduce lens flare and ghosting, as well as optical image stabilization (OIS) to reduce image blur.
Protective Elements: The lens assembly often includes protective elements like a scratch-resistant glass cover or protective coatings to safeguard the lens from damage and debris.
Mounting and Integration: The lens assembly is securely mounted within the cell phone's camera housing, ensuring that it remains stable and aligned for consistent image quality. It is also integrated with the camera's sensor, image processing electronics, and software.
Connectors and Wiring: There are connectors and wiring within the lens assembly to establish communication with the phone's image processing unit and to transmit image data.

The lens assembly in a cell phone camera is a critical component that significantly impacts the overall photographic capabilities of the device. Manufacturers invest in the design and quality of these assemblies to provide users with features like high-resolution photography, advanced focus capabilities, low-light performance, and various shooting modes. Different phone models may have different lens assembly configurations, and advancements in this technology continue to drive improvements in mobile photography.

MEMS image sensor assembly 350 may include a flux redirection assembly (e.g., flux redirection assembly 366) positioned proximate the common magnet assembly (e.g., common magnet assembly 352). The flux redirection assembly (e.g., flux redirection assembly 366) may include: one or more steel subassemblies (e.g., steel subassemblies 368, 370, 372) configured to redirect the flux of the common magnet assembly (e.g., common magnet assembly 352), as shown in magnetic flux graph 374 of FIG. 4C. FIG. 4C is a cross-sectional view of an electromagnetic actuator assembled as part of the MEMS image sensor assembly 350 of FIGS. 4A-4B, with the magnetic flex graph 374 imposed over the cross-section.

Also shown in FIG. 4B, various additional components of MEMS image sensor assembly 350 may include: autofocus coil 376 (which may be configured to interact with common magnet assembly 352 and control out-of-plane movement of out-of-plane actuation subassembly 362); autofocus spring 378 (for biasing out-of-plane actuation subassembly 362 into a default position); IR glass filter 380 (for filtering infrared light passing through lens assembly 364); IR & magnet holder 382 (for positioning lens assembly 364 & steel subassemblies 368, 370); optical image stabilization coils 384, 386 (which may be configured to interact with common magnet assembly 352 and control in-plane movement of in-plane actuation subassembly 360); top MEMS spring 388 (for biasing in-plane actuation subassembly 360 into a default position); bottom MEMS spring 390 (for biasing in-plane actuation subassembly 360 into a default position); OIS metal plate 392 (for mounting various portions of in-plane actuation subassembly 360); and RFPCB 394 (for coupling MEMS image sensor assembly 350 to a printed circuit board).

As discussed above, autofocus coil 376 may be configured to interact with common magnet assembly 352 and control out-of-plane movement of out-of-plane actuation subassembly 362, wherein optical image stabilization coils 384, 386 may be configured to interact with common magnet assembly 352 and control in-plane movement of in-plane actuation subassembly 360.

Specifically, and with respect to autofocus coil 376, by controlling the level of current passing through autofocus coil 376, a magnetic field may be generated that interacts with plurality of magnet assemblies 354 to generate attraction or repulsion forces along the Z-axis of MEMS image sensor assembly 350, thus resulting in Z-axis displacement and the effectuation of such autofocus functionality. For example, the magnetic field generated may displace the lens assembly (e.g., lens assembly 364) and/or the image sensor subassembly (e.g., image sensor subassembly 358) along the Z-axis to effectuate such autofocus functionality.

Accordingly, and with respect to autofocus coil 376, passing a current (I) through autofocus coil 376 in a first direction may result in negative Z-axis displacement, wherein the quantity of such negative Z-axis displacement may be controlled by adjusting the level of current passing through autofocus coil 376 in the first direction. Conversely, passing a current (I) through autofocus coil 376 in a second (i.e., opposite) direction may result in positive Z-axis displacement, wherein the quantity of such positive Z-axis displacement may be controlled by adjusting the level of current passing through autofocus coil 376 in the second (i.e., opposite) direction.

Further, and with respect to optical image stabilization coils 384, 386, by controlling the level of current passing through one or more of optical image stabilization coils 384, 386, a magnetic field may be generated that interacts with plurality of magnet assemblies 354 to generate attraction or repulsion forces along the X-axis and/or Y-axis of MEMS image sensor assembly 350, thus resulting in X-axis and/or Y-axis displacement and the effectuation of such optical image stabilization (OIS) functionality. For example, the magnetic field generated may displace the lens assembly (e.g., lens assembly 364) and/or the image sensor subassembly (e.g., image sensor subassembly 358) along the X-axis and/or Y-axis to effectuate such OIS functionality.

Accordingly, and with respect to optical image stabilization coils 384, 386, passing a current (I) through one or more of image stabilization coils 384, 386 in a first direction may result in negative X-axis and/or Y-axis displacement, wherein the quantity of such negative X-axis and/or Y-axis displacement may be controlled by adjusting the level of current passing through one or more of image stabilization coils 384, 386 in the first direction. Conversely, passing a current (I) through one or more of image stabilization coils 384, 386 in a second (i.e., opposite) direction may result in positive X-axis and/or Y-axis displacement, wherein the quantity of such positive X-axis and/or Y-axis displacement may be controlled by adjusting the level of current passing through one or more of image stabilization coils 384, 386 in the second (i.e., opposite) direction.

As discussed above, MEMS image sensor assembly 350 may include a flux redirection assembly (e.g., flux redirection assembly 366) positioned proximate the common magnet assembly (e.g., common magnet assembly 352). The flux redirection assembly (e.g., flux redirection assembly 366) may include one or more steel subassemblies (e.g., steel subassemblies 368, 370, 372) configured to redirect the flux (e.g., of common magnet assembly 352, of image stabilization coils 384, 386 and/or of autofocus coil 376), as shown in magnetic flux graph 374 of FIG. 4C.

While MEMS image sensor assembly 350 is shown to include a single autofocus spring (e.g., autofocus spring 378 for biasing out-of-plane actuation subassembly 362 into a default position), this is for illustrative purposes only and is not intended to be a limitation of this disclosure, as other configurations are possible and are considered to be within the scope of this disclosure. For example, MEMS image sensor assembly 350 may be configured to include multiple autofocus springs (e.g., a top autofocus spring and a bottom autofocus spring).

As discussed above, the common magnet assembly (e.g., common magnet assembly 352) may include a plurality of magnet assemblies (e.g., plurality of magnet assemblies 354). While plurality of magnet assemblies 354 is shown in FIG. 4B to include three magnet assemblies, this is for illustrative purposes only and is not intended to be a limitation of this disclosure, as other configurations are possible and are considered to be within the scope of this disclosure. For example, additional magnet assemblies (e.g., a fourth magnet assembly) may be included within common magnet assembly 352 to assist with Z-axis movement. When such additional magnet assemblies (e.g., a fourth magnet assembly) are included within common magnet assembly 352, the flux redirection assembly (e.g., flux redirection assembly 366) may include: additional steel subassemblies configured to redirect the flux (e.g., of common magnet assembly 352), of image stabilization coils 384, 386 and/or of autofocus coil 376), as shown in magnetic flux graph 374 of FIG. 4C.

### MEMS Flexures

As discussed above with reference to FIGS. 1B-1C and FIG. 2A, when configured to provide in-plane actuation functionality, a micro-electrical-mechanical system (MEMS) actuator 24 may include outer frame 30, a plurality of electrically conductive flexures 32, a MEMS actuation core 34 for attaching a payload (e.g., a device), and an attached optoelectronic device 26. The plurality of electrically conductive flexures 32 of micro-electrical-mechanical system (MEMS) actuator 24 may be curved upward and buckled to achieve the desired level of flexibility and compression. In the illustrated embodiment, the plurality of electrically conductive flexures 32 may have one end attached to MEMS actuation core 34 (e.g., the moving portion of micro-electrical-mechanical system (MEMS) actuator 24) and the other end attached to outer frame 30 (e.g., the fixed portion of micro-electrical-mechanical system (MEMS) actuator 24). The plurality of electrically conductive flexures 32 may be conductive wires that may extend above the plane (e.g., an upper surface) of micro-electrical-mechanical system (MEMS) actuator 24, and may electrically couple laterally separated components of micro-electrical-mechanical system (MEMS) actuator 24. For example, the plurality of electrically conductive flexures 32 may provide electrical signals from optoelectronic device 26 and/or MEMS actuation core 34 to outer frame 30 of micro-electrical-mechanical system (MEMS) actuator 24.

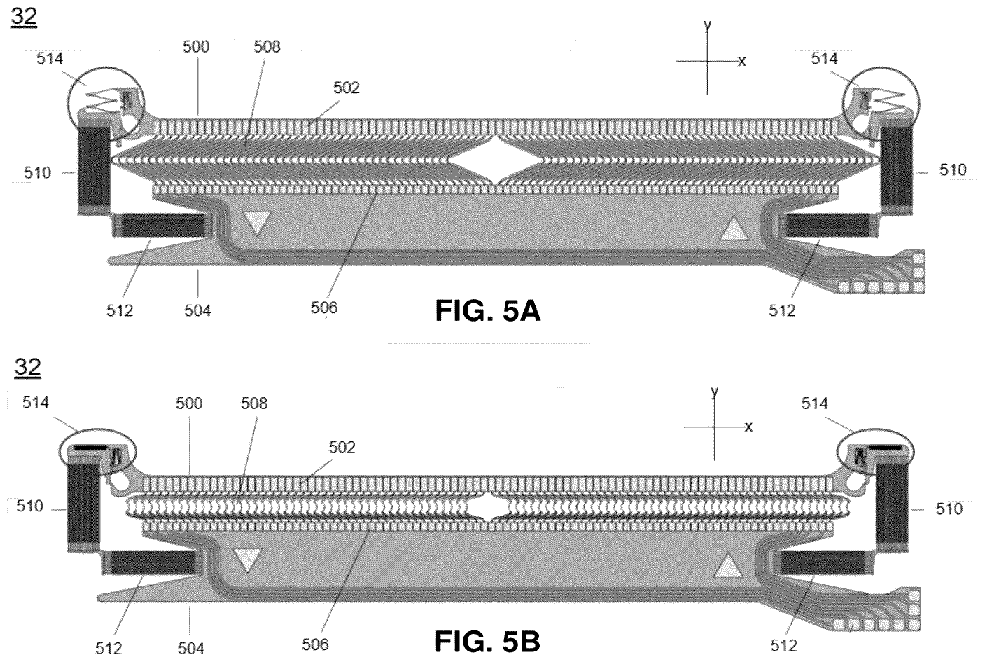

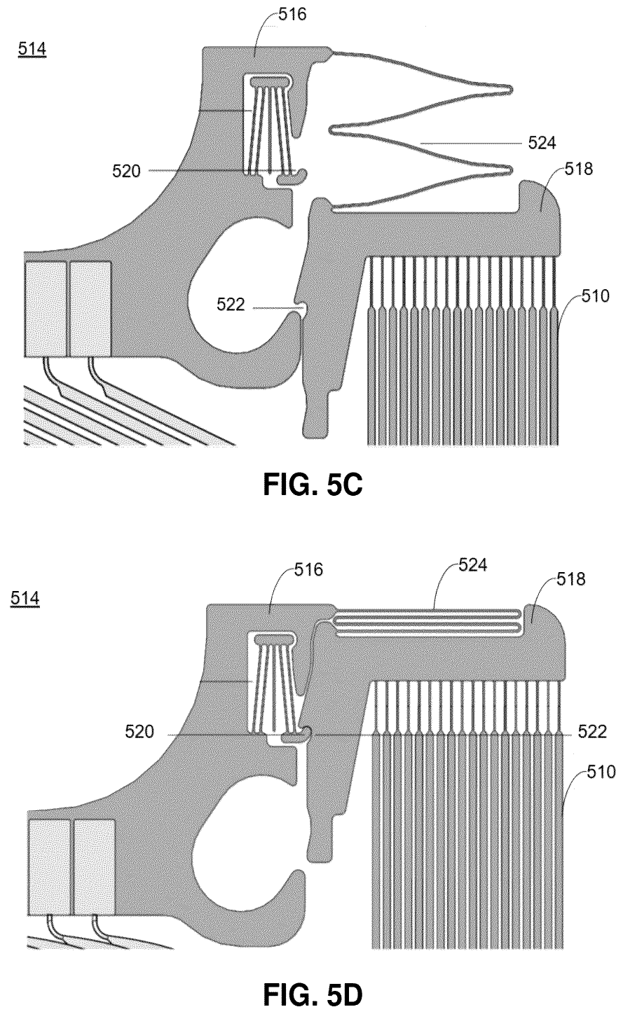

Referring also to FIG. 5A and FIG. 5B, an electrically-conductive, MEMS flexure assembly (e.g., electrically-conductive, MEMS flexure assembly 32) may include: a first MEMS subportion (e.g., first MEMS subportion 500) including a first plurality of electrically-conductive pads (e.g., a first plurality of electrically-conductive pads 502); and a second MEMS subportion (e.g., a second MEMS subportion 504) including a second plurality of electrically-conductive pads (e.g., a second plurality of electrically-conductive pads 506).

The plurality of electrically-conductive pads (e.g., the first plurality of electrically-conductive pads 502 and/or the second plurality of electrically-conductive pads 506) may include a plurality of electrically-conductive wire-bond pads, to which conductors and/or components may be electrically coupled, for example.

Electrically conductive wire-bond pads are areas on an electronic component or semiconductor device specifically designed for wire bonding. Wire bonding is a technique used in the semiconductor industry to create interconnections between an integrated circuit or chip and other components. The wire-bond pads are usually made of conductive materials like aluminum, copper, or gold and are positioned in a specific layout on the chip. They serve as connection points for thin wires, allowing electrical signals to be transmitted between the chip and other parts of the electronic circuit or other chips. Wire bonding typically involves using a fine wire made of a conductive material to create the electrical connection between the wire-bond pads on the chip and the package or substrate. This connection is often made through the process of thermosonic bonding or ultrasonic bonding, where heat, pressure, and ultrasonic energy are applied to attach the wire to the pads, establishing the electrical connection. The wire-bond pads' design and material composition play a crucial role in ensuring reliable electrical connections, signal integrity, and the overall performance of the electronic device or semiconductor component. Different types of wire-bond pads might be used based on the requirements of the specific application, the materials involved, and the manufacturing processes employed.

The plurality of electrically-conductive pads (e.g., the first plurality of electrically-conductive pads 502 and/or the second plurality of electrically-conductive pads 506) may include a plurality of electrically-conductive solder pads, to which conductors and/or components may be electrically coupled, for example.

Electrically conductive solder pads refer to specific areas or points on a substrate or electronic component designed for the application of soldering. These pads are meant to establish a conductive pathway for electrical connections, allowing components to be joined together. Solder pads are typically made from conductive materials such as copper, silver, or other metals that facilitate the soldering process. The solder, usually a metal alloy with a low melting point, is applied to these pads to create a strong mechanical and electrical bond between components. When heated, the solder melts and adheres to the conductive pads, forming a secure electrical connection upon cooling. The electrical conductivity of the pads is crucial to ensure a reliable and low-resistance pathway for the flow of electrical current. Properly designed and manufactured solder pads are essential for a solid and durable solder joint, preventing electrical discontinuities, and ensuring good signal integrity. These pads are fundamental in various electronic manufacturing processes, especially in surface-mount technology (SMT), where components are soldered directly onto the surface of a printed circuit board (PCB). Solder pads can vary in size, shape, and arrangement based on the specific requirements of the circuit design, component size, and the soldering method used in the manufacturing process.

As shown in FIGS. 5A-5B, the electrically-conductive, MEMS flexure assembly (e.g., electrically-conductive, MEMS flexure assembly 32) may include a plurality of MEMS electrically-conductive flexures (e.g., a plurality of MEMS electrically-conductive flexures 508) electrically coupling the first plurality of electrically-conductive pads (e.g., the first plurality of electrically-conductive pads 502) on the first MEMS subportion (e.g., first MEMS subportion 500) and the second plurality of electrically-conductive pads (e.g., the second plurality of electrically-conductive pads 506) on the second MEMS subportion (e.g., second MEMS subportion 504).

In MEMS devices (e.g., micro-electrical-mechanical system (MEMS) actuator 24), electrically conductive flexures (e.g., electrically-conductive, MEMS flexure assembly 32) are structural elements that provide both mechanical flexibility and electrical conductivity within the device. MEMS devices often involve tiny mechanical components and electrical circuits integrated onto a single substrate. Electrically conductive flexures play a critical role in these systems by allowing controlled movement or flexing of certain parts while maintaining electrical connectivity. These flexures can be engineered to bend or move in response to mechanical or electrical stimuli, and they can simultaneously carry electrical signals or power. They can be designed in various ways, such as serpentine structures, cantilever beams, or other flexible configurations.

Applications of electrically conductive flexures in MEMS devices include:
Sensors and Actuators: Flexures can be a part of sensors or actuators within MEMS devices. For instance, in accelerometers, the flexures might be used to detect changes in acceleration. In micro-actuators, they could facilitate movement or mechanical manipulation.
Electrical Connectivity: These flexures maintain electrical connectivity across moving parts or elements within the MEMS device. For instance, in a device where parts need to move or rotate while maintaining electrical connections, these flexures enable such movement without losing conductivity.
Signal Transmission: These flexures can also be part of transmission lines or conductive pathways that allow signals or power to pass through moving components without interruption.

The design and material used for these flexures are crucial to ensure the desired mechanical flexibility while maintaining electrical conductivity. They are often manufactured using conductive materials like metals (such as gold, copper, or aluminum) or conductive polymers, carefully structured to combine the needed mechanical and electrical properties. Their implementation is integral to the functionality and reliability of MEMS devices.

The electrically-conductive, MEMS flexure assembly (e.g., electrically-conductive, MEMS flexure assembly 32) may be configured to allow deformation of the plurality of MEMS electrically-conductive flexures (e.g., the plurality of MEMS electrically-conductive flexures 508) in two axes.

For example, the electrically-conductive, MEMS flexure assembly (e.g., electrically-conductive, MEMS flexure assembly 32) may include an X-axis displacement assembly (e.g., X-axis displacement assembly 510) configured to allow deformation of the plurality of MEMS electrically-conductive flexures (e.g., the plurality of MEMS electrically-conductive flexures 508) in the X-axis, thus allowing movement of the first MEMS subportion (e.g., first MEMS subportion 500) with respect to the second MEMS subportion (e.g., second MEMS subportion 504) along the X-axis.

Further, the electrically-conductive, MEMS flexure assembly (e.g., electrically-conductive, MEMS flexure assembly 32) may include a Y-axis displacement assembly (e.g., Y-axis displacement assembly 512) configured to allow deformation of the plurality of MEMS electrically-conductive flexures (e.g., plurality of MEMS electrically-conductive flexures 508) in the Y-axis, thus allowing movement of the first MEMS subportion (e.g., first MEMS subportion 500) with respect to the second MEMS subportion (e.g., second MEMS subportion 504) along the Y-axis.

As also shown in FIGS. 5A-5B, the electrically-conductive, MEMS flexure assembly (e.g., electrically-conductive, MEMS flexure assembly 32) may include a latching assembly (e.g., latching assembly 514) configured to couple the first MEMS subportion (e.g., first MEMS subportion 500) and the second MEMS subportion (e.g., second MEMS subportion 504) in a latched configuration (as shown in FIG. 5B and FIG. 5D).

Referring to FIG. 5C and FIG. 5D, the latching assembly (e.g., latching assembly 514) may include: a first latching portion (e.g., first latching portion 516); and a second latching portion (e.g., second latching portion 518). For example, the first latching portion (e.g., first latching portion 516) of the latching assembly (e.g., latching assembly 514) may include a biased latch bolt (e.g., biased latch bolt 520), wherein the second latching portion (e.g., second latching portion 518) of the latching assembly (e.g., latching assembly 514) may include a bolt recess (e.g., bolt recess 522) configured to receive the biased latch bolt (e.g., biased latch bolt 520) to couple the first MEMS subportion (e.g., first MEMS subportion 500) and the second MEMS subportion (e.g., second MEMS subportion 504) in the latched configuration (as shown in FIG. 5B and FIG. 5D).

As also shown in FIGS. 5C-5D, the electrically-conductive, MEMS flexure assembly (e.g., electrically-conductive, MEMS flexure assembly 32) may include a biasing assembly (e.g., biasing assembly 524) configured to bias the first MEMS subportion (e.g., first MEMS subportion 500) and the second MEMS subportion (e.g., second MEMS subportion 504) in the unlatched configuration (as shown in FIG. 5A and FIG. 5C).

MEMS Motion Stage with Position Sensor

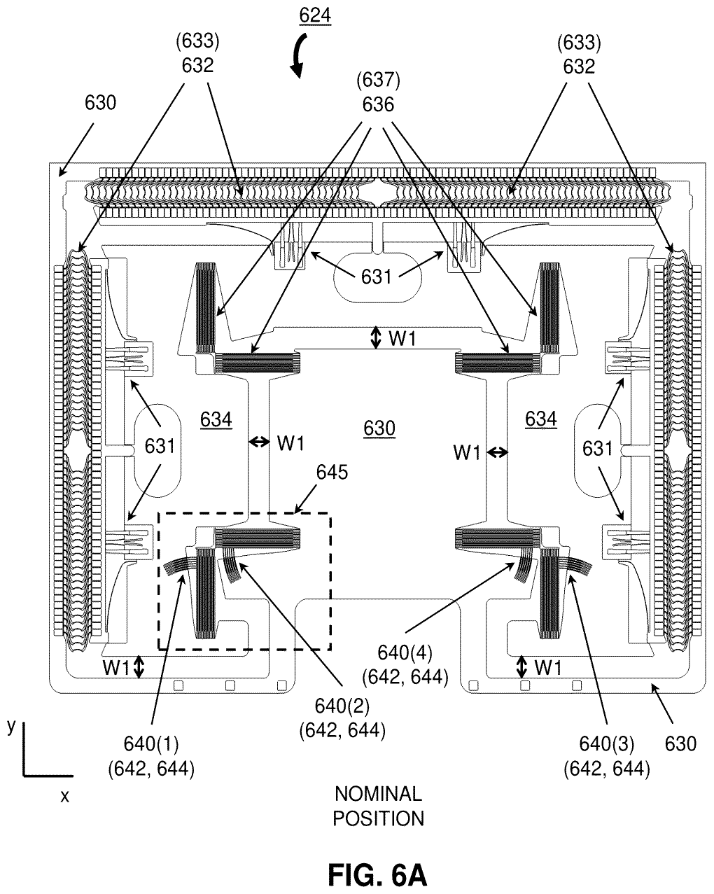

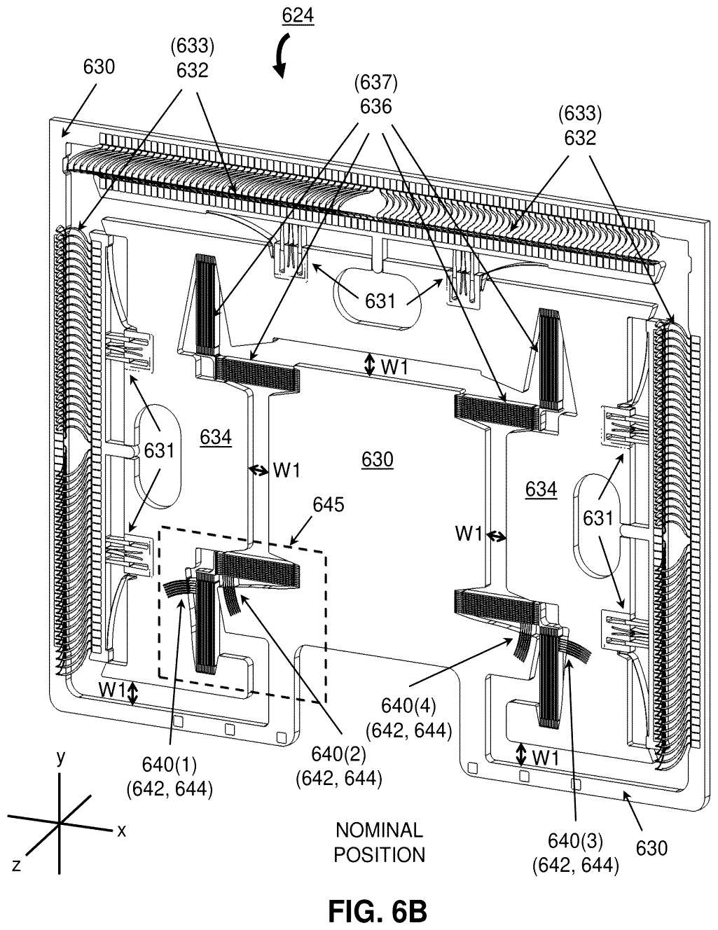

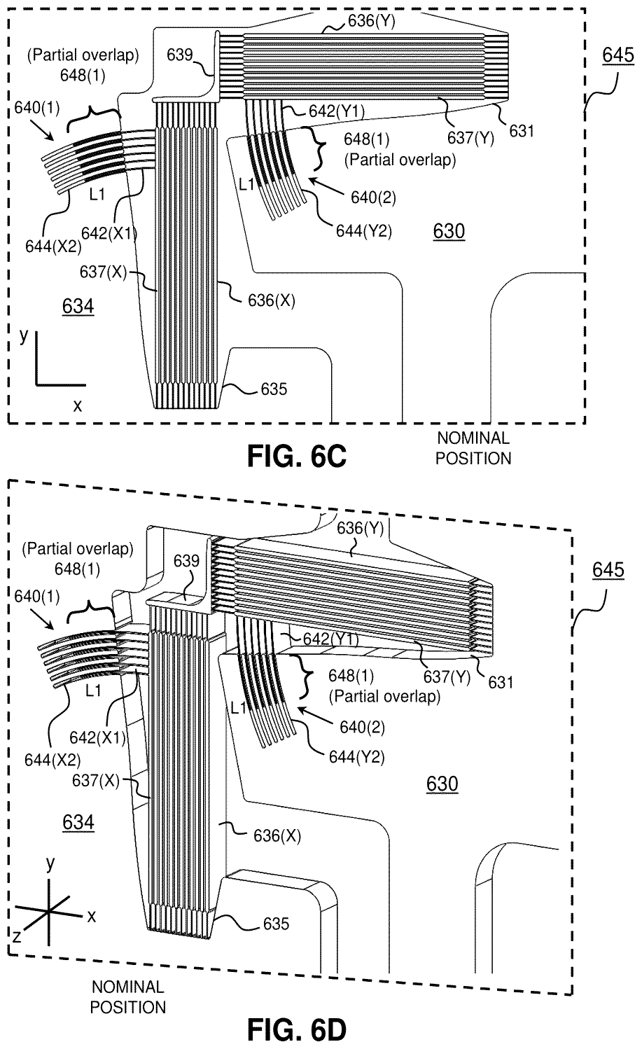

Next, a MEMS electrically-connected precision motion stage with position sensor according to aspects of the present disclosure, which incorporates a flexible electrical connection mechanism as well as a motion control mechanism and a position sensing mechanism, will be described with reference to FIGS. 6A-6D. The MEMS electrically-connected precision motion stage is designed to be compatible with other actuators (both MEMS actuators and non-MEMS actuators). As used herein, the term “motion control” refers to a set of flexurized mechanisms which connect a moving stage to a stationary stage, such that there is a precisely defined and allowed motion range between the two stages with known and controlled linear and rotational stiffness values along and around the X-axis and the Y-axis (as well as the Z-axis in some example embodiments). If an external force is applied to the moving stage, then the motion control mechanism allows for harnessing that force to move the moving stage (and any payload on the moving stage) to a precisely controlled and repeatable position.

In some example embodiments, an actuation portion (e.g., MEMS actuator 24 described above with reference to FIGS. 1A-1C and FIGS. 2A-2D) may optionally be omitted from a multi-axis MEMS assembly (e.g., multi-axis MEMS assembly 14 described above with reference to FIG. 1A) and/or from a MEMS image sensor assembly (e.g., MEMS image sensor assembly 350 described above with reference to FIGS. 4A-4B), and replaced by an electrically-connected MEMS precision motion stage as described herein. This example embodiment may be desirable for an application in which a method of actuation already exists, but that does not include one or more of the following three key features of the inventive concepts presented herein: (1) position sensing, (2) allowing electrical connections between the moving payload and the non-moving area(s), and (3) controlling or restricting the motion to follow specific stiffness along different axes (e.g., the X-axis, the Y-axis, the X and Y axes, the Z-axis, etc.). Thus, although the MEMS precision motion stage described below can be used in conjunction with an actuator, it should be appreciated that the MEMS precision motion stage could also be used for sensing or another application which does not actually require an actuator or other actuation means to generate the force by which the relative position of the moving stage and the stationary stage can be changed.

FIG. 6A is a diagrammatic view of an electrically-connected micro-electrical-mechanical system (MEMS) motion stage 624, also referred to herein as MEMS motion stage 624, and FIG. 6B is a perspective view of MEMS motion stage 624, according to an example embodiment of the present disclosure. MEMS motion stage 624 is a MEMS electrically-connected precision motion stage subassembly that enables precisely controlled motion of a payload (e.g., an attached optoelectronic device). The embodiment of FIGS. 6A-6B is an example of MEMS motion stage 624 in a first physical configuration referred to herein as a “nominal position,” when there is no motion occurring.

As shown in FIGS. 6A-6B, electrically-connected MEMS motion stage 624 includes a stationary portion 630, an electrically-conductive MEMS flexure assembly 632, a movable portion 634, and a plurality of motion control assemblies 636.

The stationary portion 630 is a fixed outer frame of the MEMS motion stage 624 in this example embodiment. The stationary portion 630 comprises an outer periphery section surrounding outer edges of movable portion 634, and a central section which is surrounded by inner edges of movable portion 634.

The electrically-conductive MEMS flexure assembly 632 comprises a plurality of electrically-conductive MEMS flexures 633, and is configured to provide a flexible electrical connection mechanism between stationary portion 630 and movable portion 634 according to an aspect of the present disclosure. In addition, a latching assembly 631 is configured to couple electrically-conductive MEMS flexure assembly 632 and movable portion 634 in a latched configuration. The latching assembly 631 shown in FIGS. 6A-6B has a similar functionality as the latching assembly 514 described above with reference to FIGS. 5A-5D, although the specific design is somewhat different, respectively. In this example embodiment, the plurality of electrically-conductive MEMS flexures 633 have a very low mechanical stiffness relative to the amount of force used in most applications, such that the electrically-conductive MEMS flexure assembly 632 allows an electrical signal to be passed between objects with relative motion without substantially affecting the amount or direction of that relative motion.

The movable portion 634 is disposed within the outer periphery section of stationary portion 630 and around the central section of stationary portion 630, and is configured to be movable along different axes (e.g., the X-axis, the Y-axis, the X-axis and the Y-axis) in response to external forces in a precise and controlled way according to an aspect of the present disclosure.

The plurality of motion control assemblies 636 each comprise a plurality of motion control flexures 637, are disposed at one or more locations between stationary portion 630 and movable portion 634 (i.e., the upper left side, the upper right side, the lower left side, and the lower right side in this example, although other configurations are possible), and are configured to provide a motion control mechanism according to an aspect of the present disclosure.

More specifically, each motion control assembly 636 comprises an X-axis displacement assembly 636(X) and a Y-axis displacement subassembly 636(Y). The X-axis displacement subassembly 636(X) comprises a plurality of X-axis motion control flexures 637(X), and the Y-axis displacement subassembly 636(Y) comprises a plurality of Y-axis motion control flexures 637(Y). The X-axis displacement subassembly 636(X) and the Y-axis displacement subassembly 636(Y) are connected together at respective ends thereof by a bracket 639.

When movable portion 634 of MEMS motion stage 624 is in the nominal position in relation to stationary portion 630, the electrically-conductive MEMS flexures 633 of each of the three MEMS flexure assemblies 632 are in a first state. The first state can be considered a nominal or default configuration, that is neither expanded/stretched nor retracted/compressed.

When movable portion 634 of MEMS motion stage 624 is in the nominal position in relation to stationary portion 630, movable portion 634 is separated from stationary portion 630 by a first width (W1) along the X-axis on both sides of the central section of stationary portion 630, and is separated by a first width (W1) along the Y-axis on a lower side of the outer periphery section of stationary portion 630.

As also shown in FIGS. 6A-6B, electrically-connected MEMS motion stage 624 further comprises a plurality of position sensors 640, including a first position sensor 640(1), a second position sensor 640(2), a third position sensor 640(3), and a fourth position sensor 640(4), which are disposed adjacent to respective motion control assemblies 636, and are configured to provide a position sensing mechanism. For example, the position sensors 640 can enable positions of motion control assemblies 636 to be determined, can enable positions of movable portion 634 relative to stationary portion 630 to be determined, and can enable directions of motion to be determined (e.g., along one or more axes), can enable degrees/amounts of motion to be determined, or the like. The position sensors 640 can be capacitive sensors that can detect several different types of motion, depending on how the capacitance values change for each of the position sensors 640(1), 640(2), 640(3), and/or 640(4), respectively. These signals (i.e., capacitance measurements) can be interpreted by a controller/processor on an external PCB, which is electrically connected to metal contact pads located on the outer periphery section of stationary portion 630 (e.g., along the bottom edge in the lower part of the figures). The structure and functionality of the position sensors 640 will be described in further detail below with reference to FIGS. 6C-6D.

FIG. 6C is a detail view 645 of motion control assemblies 636 and position sensors 640 of MEMS motion stage 624 in the nominal position, and FIG. 6D is a perspective view thereof. As shown in FIGS. 6C-6D, stationary portion 630 includes a notch 631 defined (formed) therein for retaining Y-axis displacement subassembly 636(Y), and movable portion includes a notch 635 defined (formed) therein for retaining X-axis displacement subassembly 636(X). As also shown in FIGS. 6A-6B and FIGS. 6C-6D, each position sensor 640 (e.g., position sensors 640(1), 640(2), 640(3), 640(4)) comprises a set of position sensing fingers 642, and a set of position sensing recesses 644 corresponding to the position sensing fingers 642, respectively.

In the example embodiment of FIGS. 6A-6D, each position sensor 640 includes two electrically-isolated sets of interlaced silicon fingers (i.e., position sensing fingers 642) as electrodes. Each of these electrodes will connect to thin-film metal traces which will connect them to metal pads on the outer periphery of stationary portion 630. The X-position sensing fingers 642(X1) and the Y-position sensing fingers 642(Y1) that are directly attached to a respective one of the motion control flexures 637 of motion control assemblies 636 (i.e., X-axis displacement subassembly 636(X) and Y-axis displacement subassembly 636(Y)) can be electrically shorted together and connected to a common metal pad, which in turn can be connected through metal traces or through the silicon chip itself, for example. These metal pads can be electrically connected to an external PCB or testing system through various means, such as wire-bonding, soldering, bonding with conductive epoxy, or direct contact to probes.

More specifically, as best seen in detail view 645 of FIGS. 6C-6D, a first position sensor 640(1) comprises X-axis position sensing fingers 642(X1) and X-axis position sensing recesses 644(X2), and a second position sensor 640(2) comprises Y-axis position sensing fingers 642(Y1) and Y-axis position sensing recesses 644(Y2). The X-axis position sensing fingers 642(X1) are attached to X-axis displacement subassembly 636(X). The Y-axis position sensing fingers 642(Y1) are attached to Y-axis displacement subassembly 636(Y). The X-axis position sensing recesses 644(X2) are defined (formed) in movable portion 634, and are configured to receive the X-axis position sensing fingers 642(X1). The Y-axis position sensing recesses 644(Y2) are defined (formed) in stationary portion 630, and are configured to receive the Y-axis position sensing fingers 642(Y1).

The X-axis position sensing fingers 642(X1) protrude at least partially into the X-axis position sensing recesses 644(X2), and the Y-axis position sensing fingers 642(Y1) protrude at least partially into the Y-axis position sensing recesses 644(Y2). Thus, a certain length (L) of the position sensing fingers protrudes into the respective position sensing fingers, such that the position sensing fingers have a certain overlap 648 with the position sensing recesses.

When movable portion 634 of MEMS motion stage 624 is in the nominal position in relation to stationary portion 630, a first length (L1) of X-axis position sensing fingers 642(X1) protrudes into X-axis position sensing recesses 644(X2), and the first position sensor 640(1) has a nominal overlap 648(1) (also referred to as a partial overlap 648(1) herein). Similarly, a first length (L1) of Y-axis position sensing fingers 642(Y1) protrudes into Y-axis position sensing recesses 644(Y2), and the second position sensor 640(2) also has a nominal overlap 648(1) (or partial overlap 648(1)), when in the nominal position.

When there is no relative motion between movable portion 634 and stationary portion 630, the capacitance values of the position sensors 640 (electrodes) should remain the same (e.g., a nominal value corresponding to the nominal position). Capacitance values can be measured by a controller on the external PCB, for example.

When movable portion 634 of MEMS motion stage 624 is in the nominal position in relation to stationary portion 630:
X2=C1 (no change in capacitance),
Y2=C1 (no change in capacitance),
X4=C1 (no change in capacitance), and
Y4=C1 (no change in capacitance),
   where C1 represents a nominal capacitance value when the device is at rest (i.e., no motion).

However, when there is relative motion between movable portion 634 and stationary portion 630, the capacitance values of one or more of the position sensors 640 (electrodes) will change, and the changes in capacitance values can be measured by the controller on the external PCB, for example. This change in capacitance can be used to calculate the amount of motion of movable portion 634 for use in connection with the example embodiments presented herein, for example.

In one example implementation, the electrically-connected MEMS motion stage 624 of FIGS. 6A-6D can be integrated as part of a multi-axis MEMS assembly (such as the multi-axis MEMS assembly 24 described above with reference to FIG. 1A) that further includes a payload, such as an optoelectronic device (such as the optoelectronic device 26 described above with reference to FIGS. 1A-1C). In another example implementation, the electrically-connected MEMS motion stage 624 of FIGS. 6A-6D can be integrated as part of a MEMS image sensor assembly (such as the MEMS image sensor assembly 350 described above with reference to FIGS. 4A-4B). In either of these implementations, an alternative actuator or motor would be incorporated into the system to complete the functionality. This may be desirable in applications where more force is required, or where a user has an existing actuation design but lacks the ability to transfer electrical signals from the payload to the external stationary substrate, for example.

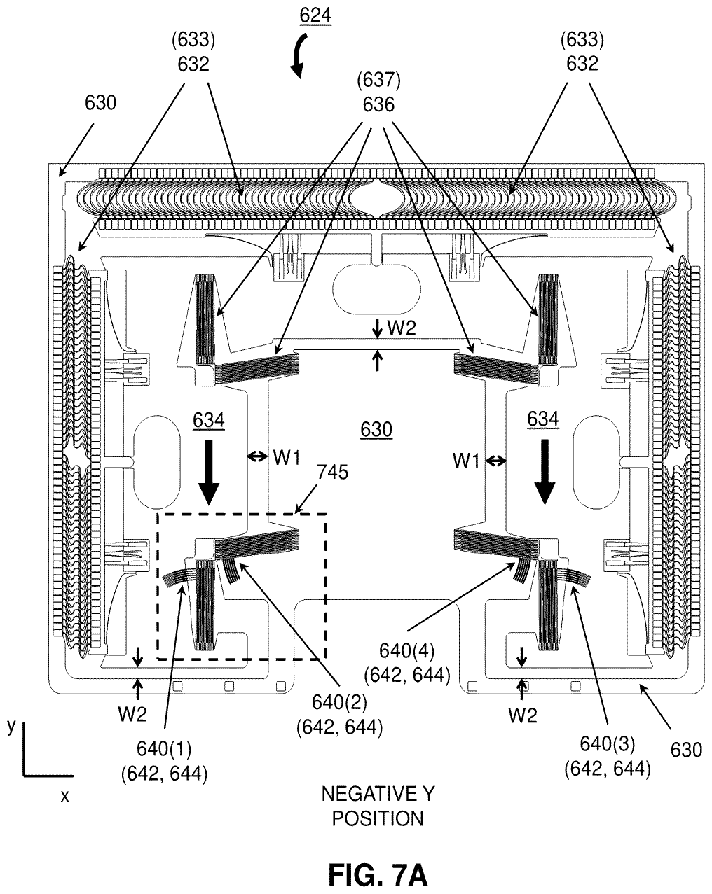

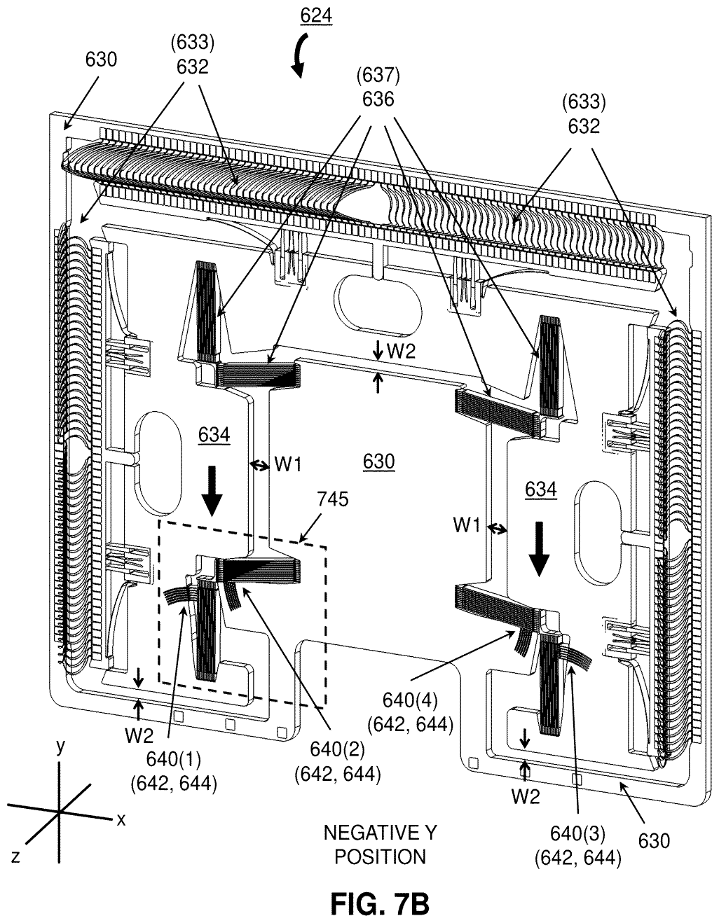

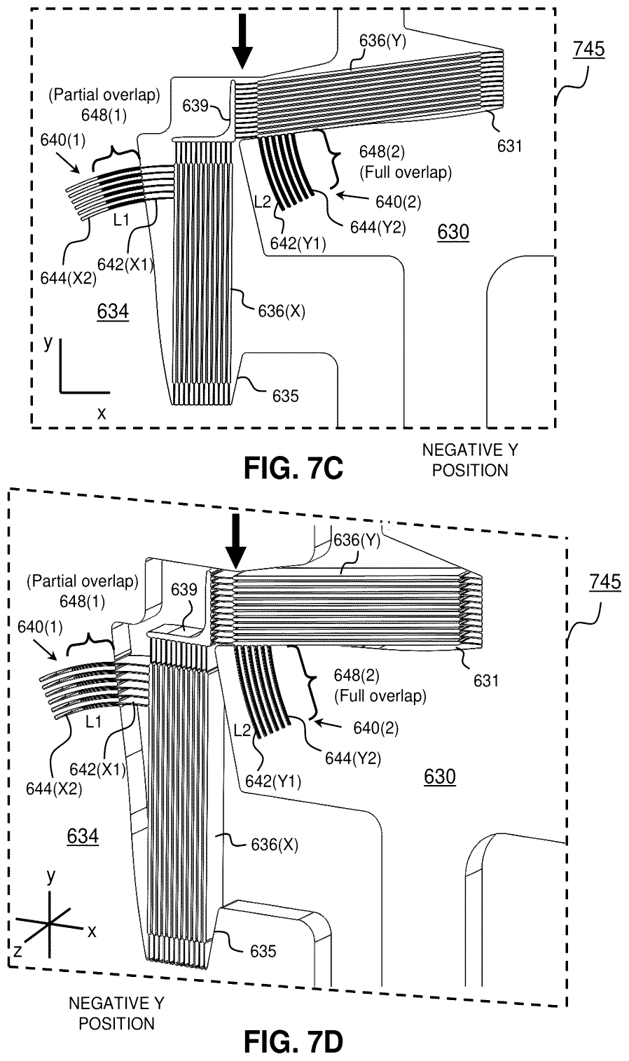

Various different examples of relative motion between movable portion 634 and stationary portion 630, and corresponding changes in positions and capacitance values, will be described below with reference to FIGS. 7A-7D, FIGS. 8A-8F, and FIGS. 9A-9F, respectively. However, it should be appreciated that these example embodiments are intended to be illustrative and should not be considered limiting or exhaustive in any way. Various other intermediate positions and different combinations of positions, and corresponding changes in capacitance values, are also possible.

FIG. 7A is another diagrammatic view of MEMS motion stage 624 and FIG. 7B is a perspective view thereof, wherein the embodiment of FIGS. 7A-7B is an example of MEMS motion stage 624 in a second physical configuration referred to herein as a “negative Y position.”

When movable portion 634 of MEMS motion stage 624 is in the negative Y position in relation to stationary portion 630, the electrically-conductive MEMS flexures 633 of the MEMS flexure assemblies 632 are in a second state. In the second state, the MEMS flexures 633 are expanded/stretched along the Y-axis due to the motion of movable portion 634 in the negative Y direction relative to stationary portion 630.

When movable portion 634 of MEMS motion stage 624 is in the negative Y position in relation to stationary portion 630, movable portion 634 is separated from stationary portion 630 by the first width (W1) along the X-axis on both sides of the central section of stationary portion 630, but is separated by a second width (W2) along the Y-axis on a lower side of the outer periphery section of stationary portion 630, where the second width W2 is smaller (i.e., narrower) than the first width W1.

FIG. 7C is a detail view 745 of motion control assemblies 636 and position sensors 640 of MEMS motion stage 624 in the negative Y position, and FIG. 7D is a perspective view thereof. As shown in detail view 745 of FIGS. 7C-7D, when movable portion 634 of MEMS motion stage 624 is in the negative Y position in relation to stationary portion 630, the first length (L1) of X-axis position sensing fingers 642(X1) protrudes into X-axis position sensing recesses 644(X2), and the first position sensor 640(1) has a nominal overlap 648(1) (or partial overlap 648(1)). A second length (L2) of Y-axis position sensing fingers 642(Y1) protrudes into Y-axis position sensing recesses 644(Y2), and the second position sensor 640(2) has a maximum overlap 648(2) (also referred to as a full overlap 648(2) herein), when in the negative Y position.

Similarly, the first length (L1) of X-axis position sensing fingers 642(X3) protrudes into X-axis position sensing recesses 644(X4), and the third position sensor 640(3) has a nominal overlap 648(1) (or partial overlap 648(1)). A second length (L2) of Y-axis position sensing fingers 642(Y3) protrudes into Y-axis position sensing recesses 644(Y4), and the fourth position sensor 640(4) has a maximum overlap 648(2) (also referred to as a full overlap 648(2) herein), when in the negative Y position.

As noted, when there is relative motion between movable portion 634 and stationary portion 630, the capacitance values of one or more of the position sensors 640 (electrodes) will change, and can be measured by the controller on the external PCB, for example. When movable portion 634 of MEMS motion stage 624 is in the negative Y position in relation to stationary portion 630:
X2=C1 (no change in capacitance),
Y2=C2 (increase in capacitance),
X4=C1 (no change in capacitance), and
Y4=C2 (increase in capacitance),
   where C2 represents an increased capacitance value that is greater than the nominal capacitance value C1. This change in capacitance can be used to calculate the amount of motion of the movable portion 634 in the −Y direction (and/or the +Y direction) for use in connection with the example embodiments presented herein.

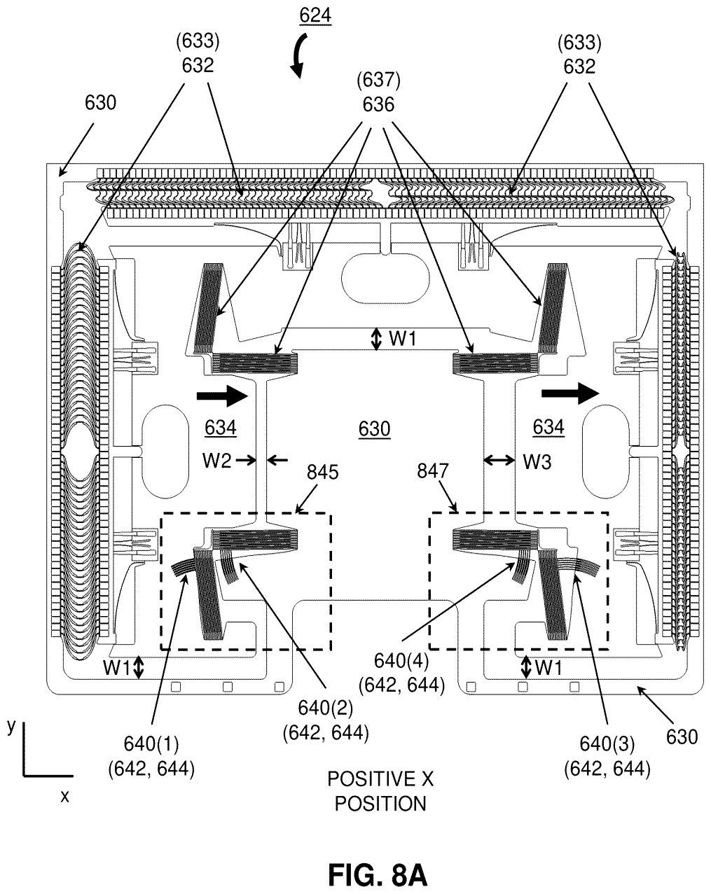

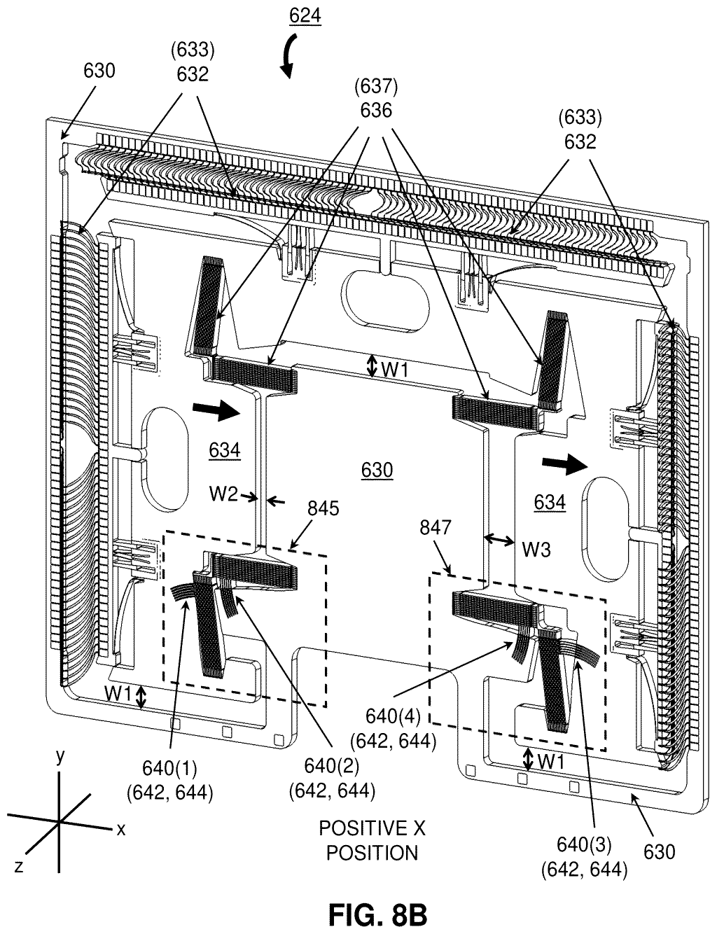

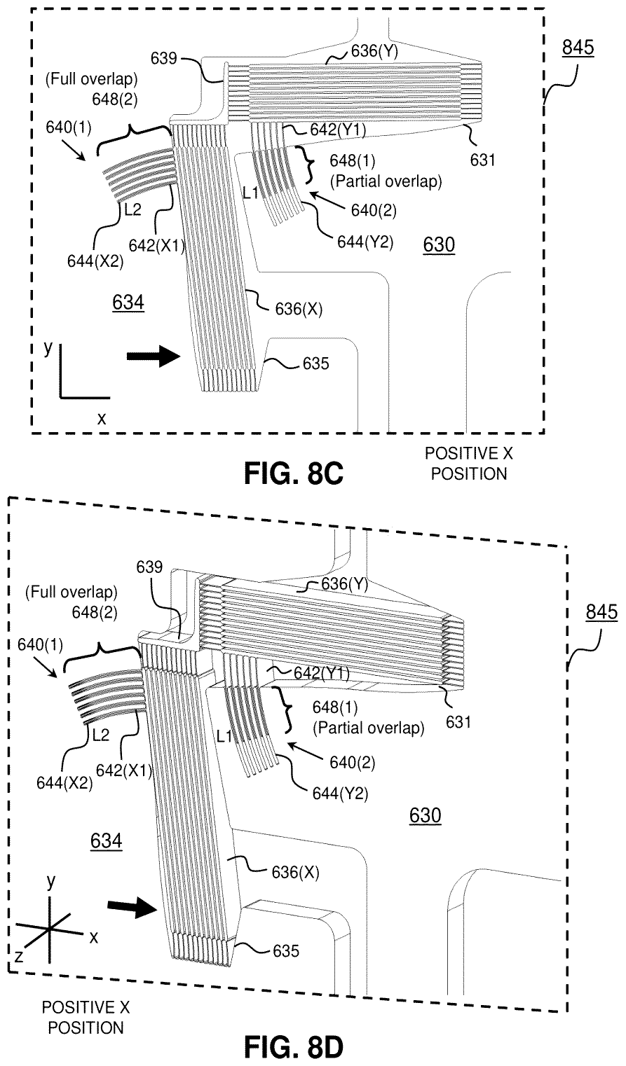

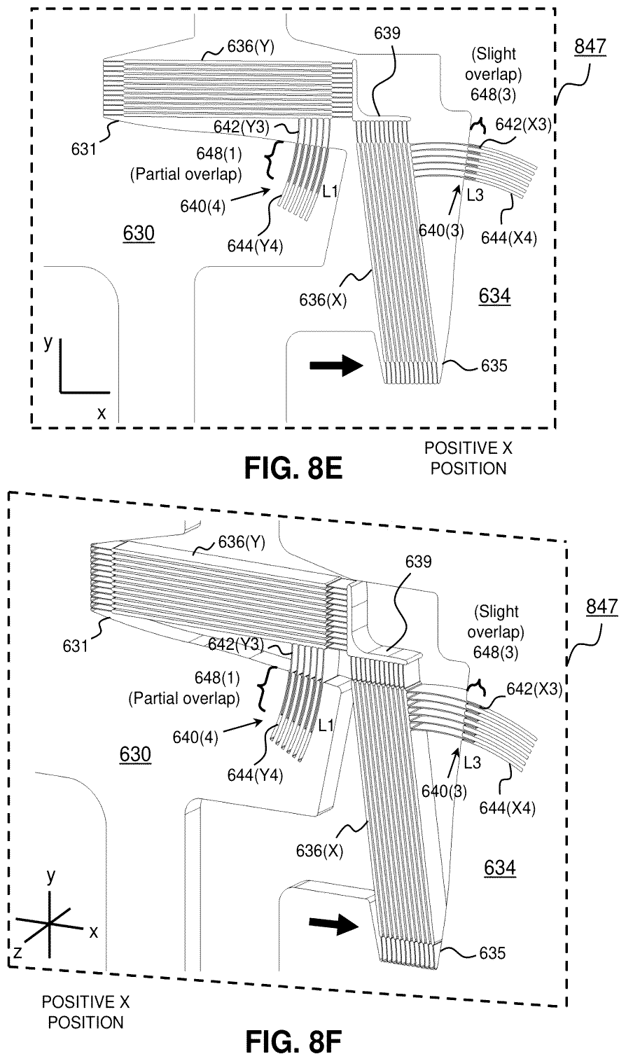

FIG. 8A is another diagrammatic view of MEMS motion stage 624, and FIG. 8B is a perspective view thereof, wherein the embodiment of FIGS. 8A-8B is an example of MEMS motion stage 624 in a third physical configuration referred to herein as a “positive X position.”

When movable portion 634 of MEMS motion stage 624 is in the positive X position in relation to stationary portion 630, the electrically-conductive MEMS flexures 633 of the MEMS flexure assemblies 632 are in a third state. In the third state, the MEMS flexures 633 are either expanded/stretched or retracted/compressed along the X-axis due to the motion of movable portion 634 in the positive X direction relative to stationary portion 630. More specifically, MEMS flexures 633 of the MEMS flexure assembly 632 at the left side of the figures expand/stretch, while MEMS flexures 632 of the MEMS flexure assembly at the right side of the figures retract/compress.

When movable portion 634 of MEMS motion stage 624 is in the positive X position in relation to stationary portion 630, movable portion 634 is separated from stationary portion 630 by the second width (W2) along the X-axis on one side of the central section of stationary portion 630 (e.g., the left side of the figures) and by a third width (W3) along the X-axis on the other side of the central section of stationary portion 630 (i.e., the right side in the figures), where the third width (W3) is larger (i.e., wider) than the first width W1. The movable portion 634 is separated from stationary portion 630 by the first width W1 along the Y-axis on the lower side of the outer periphery section of stationary portion 630 in this example.

FIG. 8C is a detail view 845 of motion control assemblies 636 and position sensors 640 of MEMS motion stage 624 in the positive X position, and FIG. 8D is a perspective view thereof. As shown in detail view 845 of FIGS. 8C-8D, when movable portion 634 of MEMS motion stage 624 is in the positive X position in relation to stationary portion 630, a second length (L2) of X-axis position sensing fingers 642(X1) protrudes into X-axis position sensing recesses 644(X2), and the first position sensor 640(1) has a maximum overlap 648(2) (or full overlap 648(2)). The first length (L1) of Y-axis position sensing fingers 642(Y1) protrudes into Y-axis position sensing recesses 644(Y2), and the second position sensor 640(2) has a nominal overlap 648(1) (or partial overlap 648(1)), when in the positive X position.

FIG. 8E is a detail view 847 of motion control assemblies 636 and position sensors 640 of MEMS motion stage 624 in the positive X position, and FIG. 8F is a perspective view thereof. As shown in detail view 847 of FIGS. 8E-8F, when movable portion 634 of MEMS motion stage 624 is in the positive X position in relation to stationary portion 630, a third length (L3) of X-axis position sensing fingers 642(X3) protrudes into X-axis position sensing recesses 644(X4), and the third position sensor 640(3) has a minimum overlap 648(3) (also referred to as a slight overlap 648(3) herein). The first length (L1) of Y-axis position sensing fingers 642(Y3) protrudes into Y-axis position sensing recesses 644(Y4), and the fourth position sensor 640(4) has a nominal overlap 648(1) (or partial overlap 648(1)), when in the positive X position.

As noted, when there is relative motion between movable portion 634 and stationary portion 630, the capacitance values of one or more of the position sensors 640 (electrodes) will change, and can be measured by the controller on the external PCB, for example. When movable portion 634 of MEMS motion stage 624 is in the positive X position in relation to stationary portion 630:
X2=C2 (increase in capacitance),
Y2=C1 (no change in capacitance),
X4=C3 (decreased capacitance), and
Y4=C1 (no change in capacitance),
   where C3 represents a decreased capacitance value that is less than the nominal capacitance value C1. These changes in capacitance can be used to calculate the amount of motion of movable portion 634 in the +X direction (and/or the −X direction) for use in connection with the example embodiments presented herein.

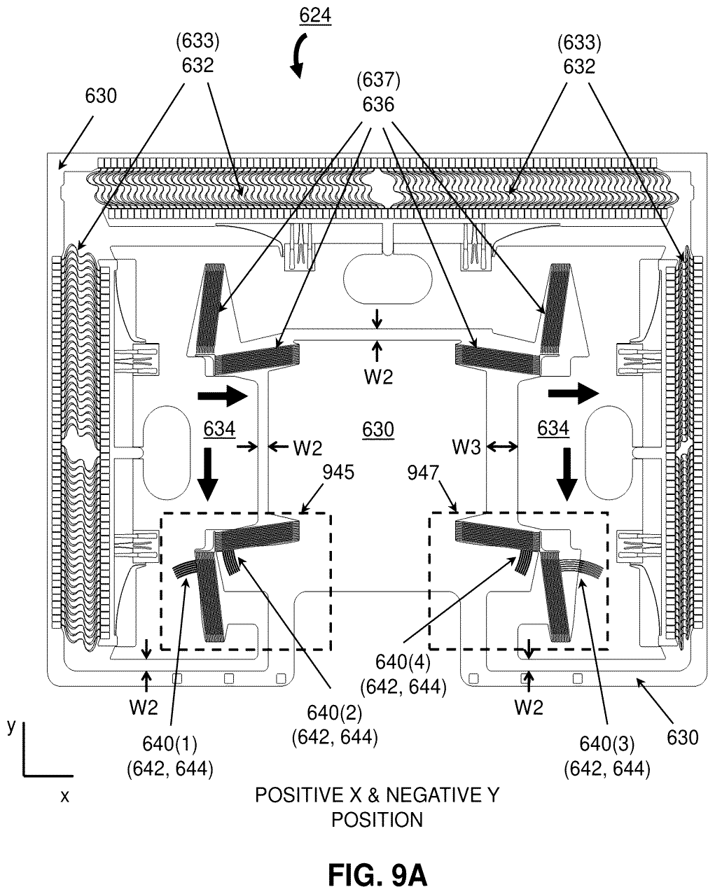

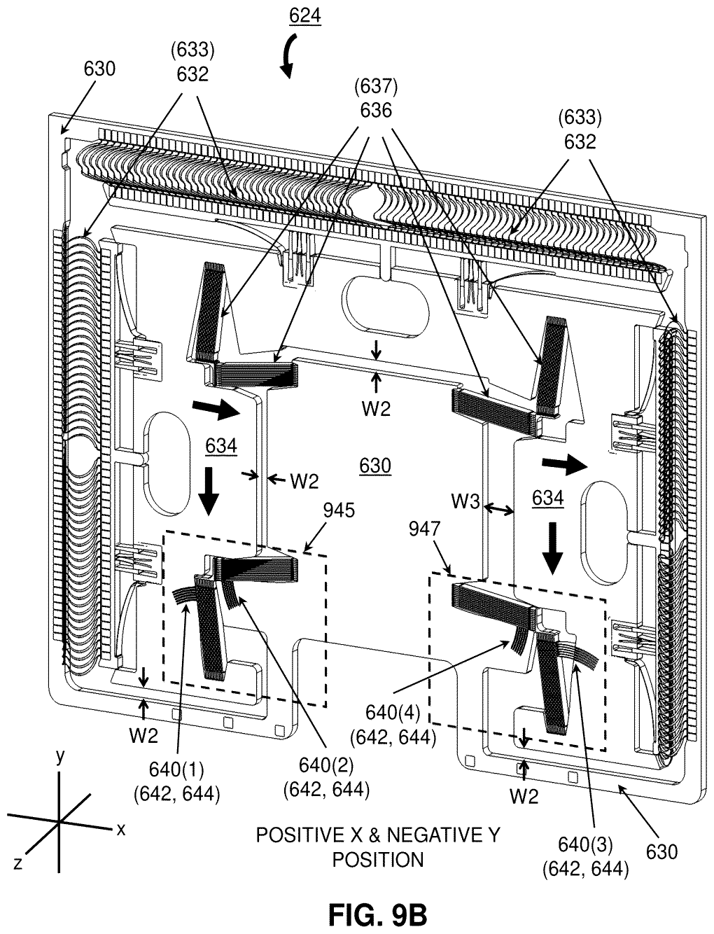

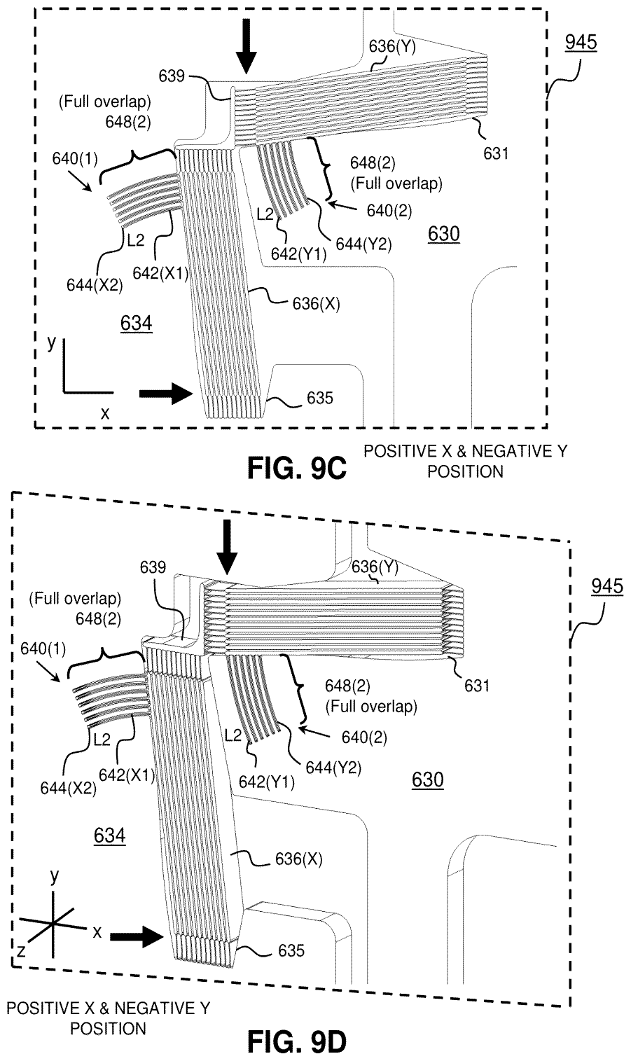

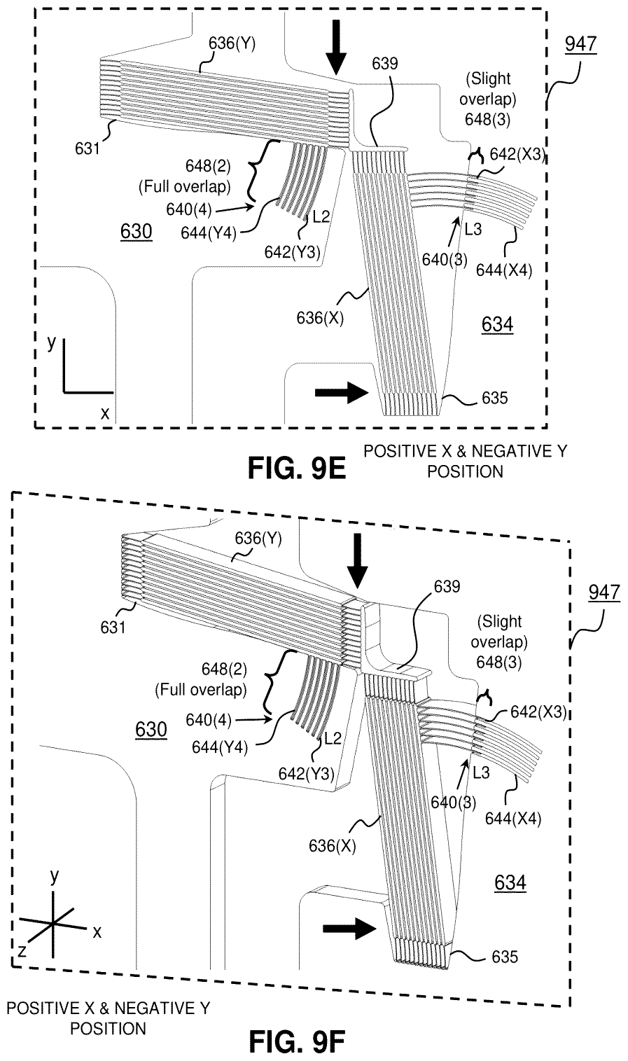

FIG. 9A is yet another diagrammatic view of MEMS motion stage 624 and FIG. 9B is a perspective view thereof, wherein the embodiment of FIGS. 9A-9B is an example of MEMS motion stage 624 in a fourth physical configuration referred to herein as a “positive X and negative Y position.”

When movable portion 634 of MEMS motion stage 624 is in the positive X and negative Y position in relation to stationary portion 630, the electrically-conductive MEMS flexures 633 of MEMS flexure assemblies 632 are in a fourth state. In the fourth state, the MEMS flexures 633 are expanded/stretched or retracted/compressed along the X-axis and the Y-axis due to the motion of movable portion 634 in the positive X direction and the negative Y direction relative to stationary portion 630. More specifically, MEMS flexures 633 of the MEMS flexure assembly 632 at the right side of the figures retract/compress, while MEMS flexures 633 of the MEMS flexure assembly 632 at the left side of the figures expand/stretch and MEMS flexures 633 of the MEMS flexure assembly 632 at the top side of the figures expand/stretch.

When movable portion 634 of MEMS motion stage 624 is in the positive X and negative Y position in relation to stationary portion 630, movable portion 634 is separated from stationary portion 630 by the second width (W2) that is smaller/narrower than W1 along the X-axis on one side of the central section of stationary portion 630 (e.g., the left side of the figure) and by the third width (W3) that is larger/wider than W1 along the X-axis on the other side of the central section of stationary portion 630 (i.e., the right side in the figure). The movable portion 634 is separated from stationary portion 630 by the second width (W2) that is smaller/narrower than W1 along the Y-axis on the lower side of the outer periphery section of stationary portion 630.

FIG. 9C is a detail view 945 of motion control assemblies 636 and position sensors 640 of MEMS motion stage 624 while in the positive X and negative Y position, and FIG. 9D is a perspective view thereof. As shown in detail view 945 of FIGS. 9C-9D, when movable portion 634 of MEMS motion stage 624 is in the positive X and negative Y position in relation to stationary portion 630, the second length (L2) of X-axis position sensing fingers 642(X1) protrudes into X-axis position sensing recesses 644(X2), and the first position sensor 640(1) has the full overlap 648(2). The second length (L2) of Y-axis position sensing fingers 642(Y1) protrudes into Y-axis position sensing recesses 644(Y2), and the second position sensor 640(2) has the full overlap 648(2), when in the positive X and negative Y position.

FIG. 9E is a detail view 947 of motion control assemblies 636 and position sensors 640 of MEMS motion stage 624 while in the positive X and negative Y position, and FIG. 9F is a perspective view thereof. As shown in detail view 947 of FIGS. 9E-9F, when movable portion 634 of MEMS motion stage 624 is in the positive X and negative Y position in relation to stationary portion 630, a third length (L3) of X-axis position sensing fingers 642(X3) protrudes into X-axis position sensing recesses 644(X4), and the third position sensor 640(3) has the slight overlap 648(3). The second length (L2) of Y-axis position sensing fingers 642(Y3) protrudes into Y-axis position sensing recesses 644(Y4), and the fourth position sensor 640(4) has the full overlap 648(2), when in the positive X and negative Y position.

As noted, when there is relative motion between the movable portion 634 and the stationary portion 630, the capacitance values of position sensors 640 (electrodes) will change, and can be measured by the controller on the external PCB, for example. When movable portion 634 of MEMS motion stage 624 is in the positive X and negative Y position in relation to the stationary portion 630:
X2=C2 (increase in capacitance),
Y2=C2 (increase in capacitance),
X4=C3 (decrease in capacitance), and
Y4=C1 (increase in capacitance),
   where the decreased capacitance C3 is less than the nominal capacitance C1 and the increased capacitance C2 is greater than the nominal capacitance C1, as noted in the above examples. These changes in capacitance can be used to calculate the amount of motion of the movable portion 634 in both the +X direction (and/or the −X direction) and in the −Y direction (and/or the +Y direction) for use in connection with the example embodiments presented herein.

In another illustrative example embodiment, the relative motion between movable portion 634 and stationary portion 630 can be a rotation motion (e.g., clockwise or counter-clockwise). In one non-limiting example of a rotation:
X2=C2 (increase in capacitance),
Y2=C2 (increase in capacitance),
X4=C3 (decrease in capacitance), and
Y4=C3 (decrease in capacitance),
   where C2 is greater than C1 and C3 is less than C1, as noted in the above examples. These changes in capacitance can be used to calculate the amount of motion of movable portion 634 in a first rotation direction (e.g., clockwise) and/or a second rotation direction (e.g., counter-clockwise) for use in connection with the example embodiments presented herein.

In yet another illustrative example embodiment, the relative motion between movable portion 634 and stationary portion 630 can be a Z-axis motion. For example, in the case of Z-axis motion:
X2=C4 (decrease in capacitance),
Y2=C4 (decrease in capacitance),
X4=C4 (decrease in capacitance), and
Y4=C4 (decrease in capacitance),
   where C4 represents a decreased capacitance value that is less than C1. It should be noted that the decreased capacitance value C4 in this example of Z-axis motion may be different from the decreased capacitance value C3 in the examples of X-axis motion described above with reference to FIGS. 8A-8F and FIGS. 9A-9F. These changes in capacitance can be used to calculate the amount of motion of movable portion 634 in the +Z direction and/or the −Z direction for use in connection with the example embodiments presented herein.

In summary, a MEMS electrically-connected precision motion stage with position sensor according to aspects of the present disclosure, which incorporates a flexible electrical connection mechanism as well as a motion control mechanism and a position sensing mechanism, has been described above with reference to FIGS. 6A-6D and the various examples of FIGS. 7A-7D, FIGS. 8A-8F, and FIGS. 9A-9F, respectively. A set of flexurized mechanisms connect the moving stage to the stationary stage such that there is a precisely defined and allowed motion range between the two stages with known and controlled linear and rotational stiffness values along and around the X-axis and the Y-axis, and possibly the Z-axis. If an external force is applied to the moving stage, then the motion control mechanism allows for harnessing that force to move the moving stage (and any payload on the moving stage) to a precisely controlled and repeatable position.

Accordingly, the MEMS electrically-connected precision motion stage according to the present disclosure provides at least the following distinct benefits/advantages: (1) position sensing, (2) allowing electrical connections between the moving payload and the non-moving area(s), and (3) controlling or restricting the motion to follow specific stiffness along different axes (e.g., the X-axis, the Y-axis, the X and Y axes, the Z-axis, etc.), among others. As noted, the MEMS electrically-connected precision motion stage with position sensor described herein is designed to be compatible with other actuators (both MEMS actuators and non-MEMS actuators), but could also be used for sensing or other applications not involving an actuator. Thus, the above-described MEMS motion stage can replace an actuator in some examples, or can be used in conjunction with an actuator in other examples.

### General

In general, the various operations of method described herein may be accomplished using or may pertain to components or features of the various systems and/or apparatus with their respective components and subcomponents, described herein.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of example block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

While various embodiments of the present disclosure have been described above, it should be understood that these embodiments have been presented by way of example only, and not of limitation. Likewise, the various diagrams may depict an example architectural or other configuration for the disclosure, which is done to aid in understanding the features and functionality that can be included in the disclosure. The disclosure is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present disclosure. Additionally, with regard to flow diagrams, operational descriptions and method claims, the order in which the steps are presented herein shall not mandate that various embodiments be implemented to perform the recited functionality in the same order unless the context dictates otherwise.

Although the disclosure is described above in terms of various example embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosure, whether or not such embodiments are described and whether or not such features are presented as being a part of a described embodiment. Thus, the breadth and scope of the present disclosure should not be limited by any of the above-described example embodiments, and it will be understood by those skilled in the art that various changes and modifications to the previous descriptions may be made within the scope of the claims.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. A number of implementations have been described in detail with reference to various example embodiments thereof, and many modifications and variations are possible and will be apparent to those of ordinary skill in the art without departing from the scope and spirit of the disclosure, as defined in the appended claims.

What is claimed is:

1. A micro-electrical-mechanical system (MEMS) motion stage comprising:
a stationary portion;
one or more electrically-conductive MEMS flexure assemblies coupled to the stationary portion;
a movable portion coupled to the one or more electrically-conductive MEMS flexure assemblies;
one or more motion control assemblies disposed between the stationary portion and the movable portion and configured to control motion of the movable portion; and
one or more position sensors disposed adjacent to the one or more motion control assemblies and configured to enable detection of movement of the movable portion in relation to the stationary portion.

2. The MEMS motion stage of claim 1, wherein the one or more electrically-conductive MEMS flexure assemblies each comprise a plurality of electrically-conductive MEMS flexures.

3. The MEMS motion stage of claim 1, wherein the one or more motion control assemblies each comprise a plurality of motion control flexures.

4. The MEMS motion stage of claim 3, wherein the one or more motion control assemblies each comprise:
an X-axis displacement assembly comprising a plurality of X-axis motion control flexures; and
a Y-axis displacement assembly comprising a plurality of Y-axis motion control flexures.

5. The MEMS motion stage of claim 4, wherein the one or more position sensors each comprise:
a plurality of position sensing fingers; and
a plurality of position sensing recesses arranged in alignment with and configured to receive the plurality of position sensing fingers.

6. The MEMS motion stage of claim 5, wherein:
the plurality of position sensing fingers comprise X-axis position sensing fingers attached to the X-axis displacement assembly, and the plurality of position sensing recesses comprise X-axis position sensing recesses formed in the movable portion for receiving the X-axis position sensing fingers; and
the plurality of position sensing fingers comprise Y-axis position sensing fingers attached to the Y-axis displacement assembly, and the plurality of position sensing recesses comprise Y-axis position sensing recesses formed in the stationary portion for receiving the Y-axis position sensing fingers.

7. The MEMS motion stage of claim 5, wherein the plurality of position sensing fingers at least partially overlap with the plurality of position sensing recesses, and the plurality of position sensing recesses have a curvature corresponding to a curvature of the plurality of position sensing fingers, respectively.

8. The MEMS motion stage of claim 1, wherein the stationary portion comprises a fixed outer frame, the movable portion has an optoelectronic device attached thereto, and the one or more positions sensors are configured to enable detection of changes in position of the movable portion in relation to the stationary portion, and the MEMS motion stage further comprises:
an actuator configured to generate controlled amounts of force in one or more directions for enabling an optical image stabilization (OIS) function for the optoelectronic device based on the changes in position of the movable portion in relation to the stationary portion.

9. A multi-axis micro-electrical-mechanical system (MEMS) assembly comprising:
an optoelectronic device; and
a MEMS motion stage coupled to the optoelectronic device, wherein the MEMS motion stage comprises:
a stationary portion;
one or more electrically-conductive MEMS flexure assemblies coupled to the stationary portion;
a movable portion coupled to the one or more electrically-conductive MEMS flexure assemblies;
one or more motion control assemblies disposed between the stationary portion and the movable portion and configured to control motion of the movable portion; and
one or more position sensors disposed adjacent to the one or more motion control assemblies and configured to enable detection of movement of the movable portion in relation to the stationary portion.

10. The multi-axis MEMS assembly of claim 9, wherein the one or more electrically-conductive MEMS flexure assemblies each comprise a plurality of electrically-conductive MEMS flexures.

11. The multi-axis MEMS assembly of claim 9, wherein the one or more motion control assemblies each comprise:
an X-axis displacement assembly comprising a plurality of X-axis motion control flexures; and
a Y-axis displacement assembly comprising a plurality of Y-axis motion control flexures.

12. The multi-axis MEMS assembly of claim 11, wherein the one or more position sensors each comprise:
a plurality of position sensing fingers; and
a plurality of position sensing recesses arranged in alignment with and configured to receive the plurality of position sensing fingers.

13. The multi-axis MEMS assembly of claim 12, wherein:
the plurality of position sensing fingers comprise X-axis position sensing fingers attached to the X-axis displacement assembly, and the plurality of position sensing recesses comprise X-axis position sensing recesses formed in the movable portion for receiving the X-axis position sensing fingers; and
the plurality of position sensing fingers comprise Y-axis position sensing fingers attached to the Y-axis displacement assembly, and the plurality of position sensing recesses comprise Y-axis position sensing recesses formed in the stationary portion for receiving the Y-axis position sensing fingers.

14. The multi-axis MEMS assembly of claim 9, wherein the optoelectronic device includes one or more of an image sensor and a lens assembly, and the MEMS motion stage includes an in-plane actuation subassembly configured to enable in-plane movement of the optoelectronic device for implementing optical image stabilization (OIS) according to feedback from the one or more position sensors.

15. A micro-electrical-mechanical system (MEMS) image sensor assembly comprising:
an image sensor subassembly including one or more image sensors;
a lens assembly; and
an in-plane MEMS motion stage subassembly coupled to the image sensor subassembly and the lens assembly, wherein the in-plane MEMS motion stage subassembly comprises:
a stationary portion;
one or more electrically-conductive MEMS flexure assemblies coupled to the stationary portion;
a movable portion coupled to the one or more electrically-conductive MEMS flexure assemblies;
one or more motion control assemblies disposed between the stationary portion and the movable portion and configured to control motion of the movable portion; and
one or more position sensors disposed adjacent to the one or more motion control assemblies and configured to enable detection of movement of the movable portion in relation to the stationary portion.

16. The MEMS image sensor assembly of claim 15, wherein the one or more electrically-conductive MEMS flexure assemblies each comprise a plurality of electrically-conductive MEMS flexures.

17. The MEMS image sensor assembly of claim 15, wherein the one or more motion control assemblies each comprise:
an X-axis displacement assembly comprising a plurality of X-axis motion control flexures; and
a Y-axis displacement assembly comprising a plurality of Y-axis motion control flexures.

18. The MEMS image sensor assembly of claim 17, wherein the one or more position sensors each comprise:
a plurality of position sensing fingers; and
a plurality of position sensing recesses arranged in alignment with and configured to receive the plurality of position sensing fingers.

19. The MEMS image sensor assembly of claim 18, wherein:
the plurality of position sensing fingers comprise X-axis position sensing fingers attached to the X-axis displacement assembly;
the plurality of position sensing recesses comprise X-axis position sensing recesses formed in the movable portion for receiving the X-axis position sensing fingers;
the plurality of position sensing fingers comprise Y-axis position sensing fingers attached to the Y-axis displacement assembly; and
the plurality of position sensing recesses comprise Y-axis position sensing recesses formed in the stationary portion for receiving the Y-axis position sensing fingers.

20. The MEMS image sensor assembly of claim 18, wherein the image sensor subassembly further includes one or more microcontrollers or processors configured to enable an optical image stabilization (OIS) function based on one or more signals or measurements obtained via the one or more position sensors, and
the in-plane MEMS motion stage subassembly includes an in-plane actuation subassembly configured to generate controlled amounts of force in one or more directions to enable in-plane movement of one or more of the image sensor subassembly and the lens assembly for implementing the OIS function.
